(19) United States
(12) Patent Application Publication
(10) Pub. No.: US 2026/0180552 A1
(43) Pub. Date: Jun. 25, 2026

(54) FILTER DEVICE

(71) Applicant: Murata Manufacturing Co., Ltd., Nagaokakyo-shi (JP)

(72) Inventors: Viktor Plesski, Gorgier (CH); Soumya Yandrapalli, Goleta, CA (US); Sean McHugh, Santa Barbara, CA (US); Gregory L. Hey-Shipton, Santa Barbara, CA (US); Garrett Williams, San Mateo, CA (US); Ventsislav Yantchev, Sofia (BG); Jesson John, Dublin, CA (US); Bryant Garcia, Mississauga (CA); Robert B. Hammond, Rockville, MD (US); Patrick Turner, Portola Valley, CA (US); Douglas Jachowski, Santa Cruz, CA (US); Greg Dyer, Santa Barbara, CA (US)

(21) Appl. No.: 19/355,036

(22) Filed: Oct. 10, 2025

Related U.S. Application Data
(63) Continuation of application No. 17/842,657, filed on Jun. 16, 2022, now Pat. No. 12,463,619.
Application No. 17/842,657 is a continuation-in-part of application No. 17/131,348, filed on Dec. 22, 2020, now Pat. No. 12,149,229.
Application No. 17/131,348 is a continuation of application No. 16/924,108, filed on Jul. 8, 2020, now Pat. No. 10,992,284.
Application No. 16/924,108 is a continuation-in-part of application No. 16/689,707, filed on Nov. 20, 2019, now Pat. No. 10,917,070.
Application No. 16/689,707 is a continuation of application No. 16/230,443, filed on Dec. 21, 2018, now Pat. No. 10,491,192.
Application No. 17/842,657 is a continuation-in-part of application No. 17/317,754, filed on May 11, 2021, now Pat. No. 11,870,424.
Application No. 17/317,754 is a continuation of application No. 17/109,812, filed on Dec. 2, 2020, now Pat. No. 11,967,945.
Application No. 17/109,812 is a continuation-in-part of application No. 16/689,707, filed on Nov. 20, 2019, now Pat. No. 10,917,070.
Application No. 16/689,707 is a continuation of application No. 16/230,443, filed on Dec. 21, 2018, now Pat. No. 10,491,192.
Application No. 17/842,657 is a continuation-in-part of application No. 17/542,295, filed on Dec. 3, 2021, now Pat. No. 12,212,306.
Application No. 17/542,295 is a continuation-in-part of application No. 17/351,201, filed on Jun. 17, 2021, now Pat. No. 11,876,498.
Application No. 17/351,201 is a continuation of application No. 16/988,213, filed on Aug. 7, 2020, now Pat. No. 11,201,601.
Application No. 16/988,213 is a continuation-in-part of application No. 16/438,121, filed on Jun. 11, 2019, now Pat. No. 10,756,697.
Application No. 16/438,121 is a continuation-in-part of application No. 16/230,443, filed on Dec. 21, 2018, now Pat. No. 10,491,192.
Application No. 17/842,657 is a continuation-in-part of application No. 17/125,960, filed on Dec. 17, 2020, now Pat. No. 11,949,402.
Application No. 17/842,657 is a continuation-in-part of application No. 17/134,213, filed on Dec. 25, 2020, now Pat. No. 12,021,496.
Application No. 17/842,657 is a continuation-in-part of application No. 17/097,238, filed on Nov. 13, 2020, now Pat. No. 11,955,952.
Application No. 17/097,238 is a continuation of application No. 16/727,304, filed on Dec. 26, 2019, now Pat. No. 10,917,072.
Application No. 17/842,657 is a continuation-in-part of application No. 17/189,246, filed on Mar. 1, 2021, now Pat. No. 11,916,539.
Application No. 17/842,657 is a continuation-in-part of application No. 17/109,848, filed on Dec. 2, 2020, now Pat. No. 12,034,428.
Application No. 17/109,848 is a continuation of application No. 17/030,050, filed on Sep. 23, 2020, now Pat. No. 10,985,728.
Application No. 17/030,050 is a continuation-in-part of application No. 16/920,173, filed on Jul. 2, 2020, now Pat. No. 11,139,794.
Application No. 16/920,173 is a continuation of application No. 16/438,121, filed on Jun. 11, 2019, now Pat. No. 10,756,697.
Application No. 16/438,121 is a continuation-in-part of application No. 16/230,443, filed on Dec. 21, 2018, now Pat. No. 10,491,192.
Application No. 17/842,657 is a continuation-in-part of application No. 17/122,977, filed on Dec. 15, 2020, now Pat. No. 11,509,279.
Application No. 17/842,657 is a continuation-in-part of application No. 17/133,857, filed on Dec. 24, 2020, now Pat. No. 11,996,825.
Application No. 17/133,857 is a continuation-in-part of application No. 17/070,694, filed on Oct. 14, 2020, now Pat. No. 11,329,628.
Application No. 17/842,657 is a continuation-in-part of application No. 17/520,689, filed on Nov. 7, 2021, now Pat. No. 12,028,049.
Application No. 17/520,689 is a continuation of application No. 17/189,246, filed on Mar. 1, 2021, now Pat. No. 11,916,539.
Application No. 17/842,657 is a continuation-in-part of application No. 17/408,264, filed on Aug. 20, 2021, now Pat. No. 12,113,512.
Application No. 17/842,657 is a continuation-in-part of application No. 17/460,077, filed on Aug. 27, 2021, now Pat. No. 12,155,371.
Application No. 17/842,657 is a continuation-in-part of application No. 17/588,803, filed on Jan. 31, 2022, now Pat. No. 12,155,374.
(60) Provisional application No. 62/685,825, filed on Jun. 15, 2018.
(60) Provisional application No. 62/685,825, filed on Jun. 15, 2018.
(60) Provisional application No. 62/685,825, filed on Jun. 15, 2018.
(60) Provisional application No. 62/701,363, filed on Jul. 20, 2018.
(60) Provisional application No. 62/701,363, filed on Jul. 20, 2018.
(60) Provisional application No. 62/701,363, filed on Jul. 20, 2018.
(60) Provisional application No. 62/701,363, filed on Jul. 20, 2018.
(60) Provisional application No. 62/741,702, filed on Oct. 5, 2018.
(60) Provisional application No. 62/741,702, filed on Oct. 5, 2018.
(60) Provisional application No. 62/741,702, filed on Oct. 5, 2018.
(60) Provisional application No. 62/741,702, filed on Oct. 5, 2018.
(60) Provisional application No. 62/748,883, filed on Oct. 22, 2018.
(60) Provisional application No. 62/748,883, filed on Oct. 22, 2018.
(60) Provisional application No. 62/748,883, filed on Oct. 22, 2018.
(60) Provisional application No. 62/748,883, filed on Oct. 22, 2018.
(60) Provisional application No. 62/753,815, filed on Oct. 31, 2018.
(60) Provisional application No. 62/753,815, filed on Oct. 31, 2018.
(60) Provisional application No. 62/753,815, filed on Oct. 31, 2018.
(60) Provisional application No. 62/753,815, filed on Oct. 31, 2018.
(60) Provisional application No. 62/865,798, filed on Jun. 24, 2019.
(60) Provisional application No. 62/892,980, filed on Aug. 28, 2019.
(60) Provisional application No. 62/904,152, filed on Sep. 23, 2019.
(60) Provisional application No. 62/904,233, filed on Sep. 23, 2019.
(60) Provisional application No. 62/983,403, filed on Feb. 28, 2020.
(60) Provisional application No. 62/983,403, filed on Feb. 28, 2020.
(60) Provisional application No. 63/040,440, filed on Jun. 17, 2020.
(60) Provisional application No. 63/053,584, filed on Jul. 18, 2020.
(60) Provisional application No. 63/072,595, filed on Aug. 31, 2020.
(60) Provisional application No. 63/072,595, filed on Aug. 31, 2020.
(60) Provisional application No. 63/087,792, filed on Oct. 5, 2020.
(60) Provisional application No. 63/087,792, filed on Oct. 5, 2020.
(60) Provisional application No. 63/088,344, filed on Oct. 6, 2020.
(60) Provisional application No. 63/088,344, filed on Oct. 6, 2020.
(60) Provisional application No. 63/167,510, filed on Mar. 29, 2021.
(60) Provisional application No. 63/167,506, filed on Mar. 29, 2021.
(60) Provisional application No. 63/169,875, filed on Apr. 2, 2021.
(60) Provisional application No. 63/228,990, filed on Aug. 3, 2021.

(51) Int. Cl. H03H 9/56; H03H 3/02; H03H 9/02; H03H 9/13; H03H 9/17; H10N 30/87

(52) U.S. Cl. CPC H03H 9/568; H03H 9/02015; H03H 9/02031; H03H 9/02062; H03H 9/02228; H03H 9/132; H03H 9/174; H03H 9/176; H03H 9/562; H03H 9/564; H03H 3/02; H03H 2003/023; H03H 9/02039; H10N 30/877

(57) ABSTRACT

Filter devices are disclosed. A filter device a first chip having a substrate; a piezoelectric layer attached either directly or via one or more intermediate layers the substrate; and one or more electrodes of a respective plurality of resonators of the first chip including a shunt resonator of the first chip; a first dielectric layer having a first thickness at least partially on the one or more electrodes of the shunt resonator; a second chip having a substrate a piezoelectric layer attached either directly or via one or more intermediate layers to the substrate; and one or more electrodes of a respective plurality of resonators of the second chip including a series resonator of the second chip; a second dielectric layer having a second thickness different than the first thickness at least partially on the one or more electrodes of the series resonator of the second chip.

### CROSS REFERENCE TO RELATED APPLICATIONS

This application is a continuation of U.S. Application patent application Ser. No. 17/842,657, filed Jun. 16, 2022.

U.S. Application patent application Ser. No. 17/842,657 is a continuation-in-part of U.S. Application patent application Ser. No. 17/131,348, filed Dec. 22, 2020, now issued as U.S. Pat. No. 12,149,229, which is a continuation of U.S. Application patent application Ser. No. 16/924,108, filed Jul. 8, 2020, now issued as U.S. Pat. No. 10,992,284 and a continuation-in-part of application Ser. No. 17/109,812, filed Sep. 23, 2020, now issued as U.S. Pat. No. 12,034,428, both of which are a continuation-in-part of U.S. Application patent application Ser. No. 16/689,707, filed Nov. 20, 2019, now issued as U.S. Pat. No. 10,917,070, which is a continuation of U.S. Application patent application Ser. No. 16/230,443, filed Dec. 21, 2018, now issued as U.S. Pat. No. 10,491,192, which claims priority from the following provisional patent applications: No. 62/685,825, filed Jun. 15, 2018; No. 62/701,363, filed Jul. 20, 2018; No. 62/741,702, filed Oct. 5, 2018; No. 62/748,883, filed Oct. 22, 2018; and No. 62/753,815 filed Oct. 31, 2018.

U.S. Application patent application Ser. No. 17/842,657 is also a continuation-in-part of U.S. Application patent application Ser. No. 17/542,295, filed Dec. 3, 2021, now issued as U.S. Pat. No. 12,212,306, which claims priority to Provisional Application No. 63/228,990 and is a continuation-in-part of U.S. Application patent application Ser. No. 17/351,201, filed Jun. 17, 2021, now issued as U.S. Pat. No. 11,876,498, which is a continuation of U.S. Application patent application Ser. No. 16/988,213, filed Aug. 7, 2020, now issued as U.S. Pat. No. 11,201,601, which claims priority to the following provisional applications: No. 62/892,980, filed Aug. 28, 2019, and No. 62/904,152, filed Sep. 23, 2019. U.S. application patent application Ser. No. 16/988,213 is a continuation-in-part of application Ser. No. 16/438,121, filed Jun. 11, 2019, now issued as U.S. Pat. No. 10,756,697, which is a continuation-in-part of application Ser. No. 16/230,443, now U.S. Pat. No. 10,491,192, which claims priority from the following provisional patent applications: No. 62/685,825, filed Jun. 15, 2018; No. 62/701,363, filed Jul. 20, 2018; No. 62/741,702, filed Oct. 5, 2018; No. 62/748,883, filed Oct. 22, 2018; and No. 62/753,815 filed Oct. 31, 2018.

U.S. Application patent application Ser. No. 17/842,657 is a continuation-in-part of U.S. Application patent application Ser. No. 17/125,960, filed Dec. 17, 2020, now issued as U.S. Pat. No. 11,949,402, and U.S. Application patent application Ser. No. 17/134,213, filed Dec. 25, 2020, now issued as U.S. Pat. No. 12,021,496 both of which claims priority to the following provisional applications: No. 63/087,792, filed Oct. 5, 2020; and No. 63/072,595, Aug. 31, 2020.

U.S. Application patent application Ser. No. 17/842,657 is a continuation-in-part of application Ser. No. 17/097,238, filed Nov. 13, 2020, now issued as U.S. Pat. No. 11,955,592, which is a continuation of U.S. Application patent application Ser. No. 16/727,304, filed Dec. 26, 2019, now issued as U.S. Pat. No. 10,917,072, which claims priority from Provisional Application No. 62/865,798, filed Jun. 24, 2019.

U.S. Application patent application Ser. No. 17/842,657 is a continuation-in-part of U.S. Application patent application Ser. No. 17/189,246, filed Mar. 1, 2021, now issued as U.S. Pat. No. 11,916,539, which claims priority from Provisional Application No. 62/983,403, filed Feb. 28, 2020.

U.S. Application patent application Ser. No. 17/842,657 is a continuation-in-part of U.S. patent application Ser. No. 17/109,848, Dec. 2, 2020, now issued as U.S. Pat. No. 12,034,428, which is a continuation of U.S. patent application Ser. No. 17/030,050, filed Sep. 23, 2020, now issued as U.S. Pat. No. 10,985,728, which claims priority from Provisional Application No. 62/904,233, filed Sep. 23, 2019, and is a continuation-in-part of U.S. patent application Ser. No. 16/920,173, filed Jul. 2, 2020, now issued as U.S. Pat. No. 11,139,794. which is a continuation of U.S. patent application Ser. No. 16/438,121, filed Jun. 11, 2019, now issued as U.S. Pat. No. 10,756,697, which is a continuation-in-part of U.S. Application patent application Ser. No. 16/230,443, filed Dec. 21, 2018, now issued as U.S. Pat. No. 10,491,192, which claims priority from the following provisional patent applications: No. 62/685,825, filed Jun. 15, 2018; No. 62/701,363, filed Jul. 20, 2018; No. 62/741,702, filed Oct. 5, 2018; No. 62/748,883, filed Oct. 22, 2018; and No. 62/753,815 filed Oct. 31, 2018.

U.S. Application patent application Ser. No. 17/842,657 is a continuation-in-part of U.S. patent application Ser. No. 17/122,977, filed Dec. 15, 2020, now issued as U.S. Pat. No. 11,509,279, which claims priority to Provisional Application No. 63/053,584, filed Jul. 18, 2020, and Provisional Application No. 63/088,344, filed Oct. 6, 2020.

U.S. Application patent application Ser. No. 17/842,657 is a continuation-in-part of U.S. patent application Ser. No. 17/133,857, filed Dec. 24, 2020, now issued as U.S. Pat. No. 11,996,825, which claims priority from Provisional Application No. 63/088,344, filed Oct. 6, 2020, and is a continuation-in-part of application Ser. No. 17/070,694, filed Oct. 14, 2020, now issued as U.S. Pat. No. 11,329,628, which claims priority to Provisional Application No. 63/040,440, filed Jun. 17, 2020.

U.S. Application patent application Ser. No. 17/842,657 is a continuation-in-part of U.S. patent application Ser. No. 17/520,689, filed Nov. 7, 2021, now issued as U.S. Pat. No. 12,028,049, which is a continuation of U.S. patent application Ser. No. 17/189,246, filed Mar. 1, 2021, now issued as U.S. Pat. No. 11,916,539, which claims priority from Provisional Application No. 62/983,403, filed Feb. 28, 2020.

U.S. Application patent application Ser. No. 17/842,657 is a continuation-in-part of U.S. patent application Ser. No. 17/408,264, filed Aug. 20, 2021, now issued as U.S. Pat. No. 12,113,512, which claims priority from Provisional Application No. 63/167,510, filed Mar. 29, 2021.

U.S. Application patent application Ser. No. 17/842,657 is a continuation-in-part of U.S. patent application Ser. No. 17/460,077, filed Aug. 27, 2021, now issued as U.S. Pat. No. 12,155,371, which claims priority from Provisional Application No. 63/167,506, filed Mar. 29, 2021.

U.S. Application patent application Ser. No. 17/842,657 is a continuation-in-part of U.S. patent application Ser. No. 17/588,803, filed Jan. 31, 2022, now issued as U.S. Pat. No. 12,155,374, which claims priority from Provisional Application No. 63/169,875, filed Apr. 2, 2021.

All of these applications listed above are hereby incorporated by reference in their entireties.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a passband or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5th generation mobile networks is defined in the 5G NR (new radio) standard. The 5G NR standard defines several new communications bands. Two of these new communications bands are N77, which uses the frequency range from 3300 MHz to 4200 MHz, and N79, which uses the frequency range from 4400 MHz to 5000 MHz. Both band N77 and band N79 use time-division duplexing (TDD), such that a communications device operating in band N77 and/or band N79 use the same frequencies for both uplink and downlink transmissions. Bandpass filters for bands N77 and N79 must be capable of handling the transmit power of the communications device. WiFi bands at 5 GHz and 6 GHz also require high frequency and wide bandwidth. The 5G NR standard also defines millimeter wave communication bands with frequencies between 24.25 GHz and 40 GHz.

### BRIEF DESCRIPTION OF THE DRAWINGS

FIG. 1 includes a schematic plan view and two schematic cross-sectional views of a transversely-excited film bulk acoustic resonator (XBAR).

FIG. 2 is an expanded schematic cross-sectional view of a portion of the XBAR of FIG. 1.

FIG. 3A is an alternative schematic cross-sectional view of the XBAR of FIG. 1.

FIG. 3B is another alternative schematic cross-sectional view of the XBAR of FIG. 1.

FIG. 3C is an alternative schematic plan view of an XBAR.

FIG. 4 is a graphic illustrating a shear horizontal acoustic mode in an XBAR.

FIG. 5 is a chart of the admittance of a simulated XBAR.

FIG. 6 is a chart comparing the admittances of three simulated XBARs with different dielectric layers.

FIG. 7 is a chart comparing the admittances of four simulated XBARs with different dielectric layer thicknesses.

FIG. 8 is a plot showing the effect of piezoelectric plate thickness on resonance frequency of an XBAR.

FIG. 9 is a plot showing the effect of front dielectric layer thickness on resonance frequency of an XBAR.

FIG. 10 is a plot showing the effect of IDT finger pitch on resonance frequency of an XBAR.

FIG. 11 is a chart comparing the admittances of XBARs on LiNbO3 and LiTaO3 plates.

FIG. 12 is a chart of the measured admittance of an XBAR.

FIG. 13 is another chart of the measured admittance of an XBAR.

FIG. 14 is a schematic circuit diagram and layout of a filter using XBARs.

FIG. 15 is a schematic circuit diagram of a filter using XBARs with multiple frequency setting dielectric layers.

FIG. 16 is a graph of the input-output transfer function (S21) of an embodiment of the filter of FIG. 15.

FIG. 17 is a graph of the resonance frequencies of the XBARs in the embodiment of FIG. 16 as a function of IDT pitch with frequency setting dielectric layer thickness as a parameter.

FIG. 18 is a graph of resonance frequency as a function of IDT pitch and frequency setting dielectric layer thickness.

FIG. 19 is a flow chart of a process for fabricating a filter using XBARs with multiple frequency setting dielectric layers.

FIG. 20 is a graph of the transfer curve (S21) of an embodiment of the filter of FIG. 12.

FIG. 21 is a graph of the transfer curve (S21) of another embodiment of the filter of FIG. 12.

FIG. 22A is a schematic diagram of an exemplary RF ladder filter circuit incorporating acoustic wave resonators.

FIG. 22B is a schematic diagram of an alternative implementation of an RF ladder filter circuit incorporating acoustic wave resonators.

FIG. 23A is a simplified schematic cross-sectional view of a first acoustic wave resonator.

FIG. 23B is a simplified schematic cross-sectional view of a second acoustic wave resonator.

FIG. 34A is a simplified schematic cross-sectional view of a third acoustic wave resonator.

FIG. 24B a simplified schematic cross-sectional view of a fourth acoustic wave resonator

FIG. 25A a simplified schematic cross-sectional view of a fifth acoustic wave resonator.

FIG. 25B a simplified schematic cross-sectional view of a sixth acoustic wave resonator

FIG. 26 is a simplified schematic plan view of a traditional ladder filter.

FIG. 27 is a simplified schematic plan view of a split ladder implementation of a band-pass filter.

FIG. 28 is a simplified schematic cross-sectional view of a split ladder implementation of the exemplary band-pass filter of FIG. 27.

FIG. 29 is a chart comparing S12 of two implementations of an exemplary band-pass filter.

FIG. 30 is a chart of S12 of a split ladder implementation of the exemplary band-pass filter.

FIG. 31A is a simplified schematic plan view of a two-chip duplexer.

FIG. 31B is a simplified schematic plan view of a split ladder implementation of a duplexer.

FIG. 32 is a simplified schematic plan view of another split ladder implementation of a duplexer.

FIG. 33 is a flow chart of a method for fabricating a split ladder filter device.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

### Description of Apparatus

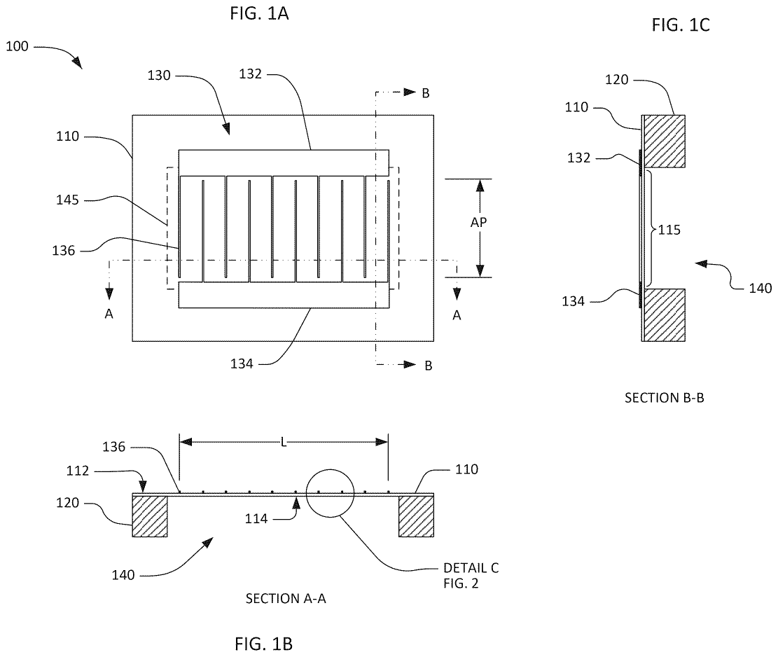

FIG. 1 shows a simplified schematic top view and orthogonal cross-sectional views of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz.

The XBAR 100 is made up of a thin film conductor pattern formed on a surface of a piezoelectric plate 110 having substantially parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are Z-cut, which is to say the Z axis is normal to the surfaces. However, XBARs may be fabricated on piezoelectric plates with other crystallographic orientations including rotated Z-cut and rotated Y-cut.

A portion of the back surface 114 of the piezoelectric plate 110 is attached to a substrate 120 that provides mechanical support to the piezoelectric plate 110. A cavity 140 is formed in the substrate. “Cavity” has its conventional meaning of “an empty space within a solid body.” The cavity 140 may be a hole completely through the substrate 120 (as shown in Section A-A and Section B-B) or a recess in the substrate 120. The cavity 140 may be formed, for example, by selective etching of the substrate 120. The dashed line 145 in the plan view is the perimeter of the cavity 140, which is defined by the intersection of the cavity and the back surface 114 of the piezoelectric plate 110. As shown in FIG. 1, the perimeter 145 of the cavity 140 has a rectangular shape with an extent greater than the aperture AP and length L of the IDT 130. A cavity of an XBAR may have a different shape, such as a regular or irregular polygon. The cavity of an XBAR may more or fewer than four sides, which may be straight or curved.

The portion of the piezoelectric plate 110 outside of the perimeter 145 of the cavity 140 is attached to the substrate. This portion may be referred to as the “supported portion” of the piezoelectric plate. The portion 115 of the piezoelectric plate 110 within the perimeter 145 of the cavity 140 is suspended over the cavity 140 without contacting the substrate 120. The portion 115 of the piezoelectric plate 110 that spans the cavity 140 will be referred to herein as the “diaphragm” 115 due to its similarity to the diaphragm of a microphone.

The substrate 120 may be, for example, silicon, sapphire, quartz, or some other material. The supported portion of the piezoelectric plate 110 may be bonded to the substrate 120 using a wafer bonding process, or grown on the substrate 120, or attached to the substrate in some other manner. The piezoelectric plate may be attached directly to the substrate or may be attached to the substrate via one or more intermediate material layer.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The term “busbar” is commonly used to identify the electrodes that connect the fingers of an IDT. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites an acoustic wave within the piezoelectric plate 110. As will be discussed in further detail, the excited acoustic wave is a bulk shear wave that propagates in the direction normal to the surface of the piezoelectric plate 110, which is also normal, or transverse, to the direction of the electric field created by the IDT fingers. Thus, the XBAR is considered a transversely-excited film bulk wave resonator.

The rectangular area defined by the length L and the aperture AP is considered the “transducer area”. Substantially all the conversion between electrical and acoustic energy occurs within the transducer area. The electric fields formed by the IDT may extend outside of the transducer area. The acoustic waves excited by the IDT are substantially confined within the transducer area. Small amounts of acoustic energy may propagate outside of the transducer area in both the length and aperture directions. In other embodiments of an XBAR, the transducer area may be shaped as a parallelogram or some other shape rather than rectangular. All the overlapping portions of the IDT fingers and the entire transducer area are positioned on the diaphragm 115, which is to say within the perimeter of the cavity defined by the dashed line 145.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 130. An XBAR may have hundreds, possibly thousands, of parallel fingers in the IDT 130. Similarly, the thickness of the fingers in the cross-sectional views is greatly exaggerated.

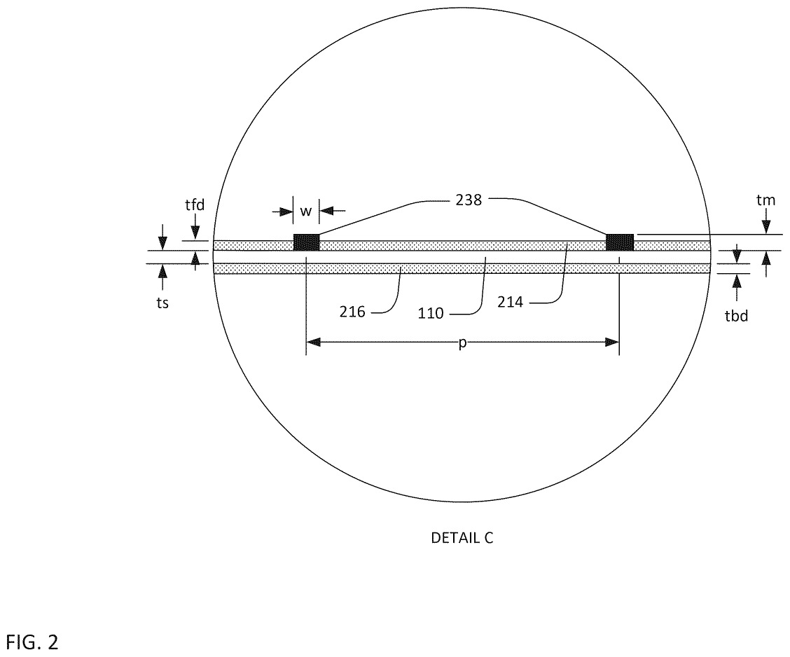

FIG. 2 shows a detailed schematic cross-sectional view of the XBAR 100. The piezoelectric plate 110 is a single-crystal layer of piezoelectrical material having a thickness ts. ts may be, for example, 100 nm to 1500 nm. When used in filters for LTE™ bands from 3.4 GHZ to 6 GHZ (e.g., bands 42, 43, 46), the thickness ts may be, for example, 200 nm to 1000 nm.

A front-side dielectric layer 214 may optionally be formed on the front side of the piezoelectric plate 110. The “front side” of the XBAR is, by definition, the surface facing away from the substrate. The front-side dielectric layer 214 has a thickness tfd. The front-side dielectric layer 214 is formed between the IDT fingers 238. Although not shown in FIG. 2, the front side dielectric layer 214 may also be deposited over the IDT fingers 238. A back-side dielectric layer 216 may optionally be formed on the back side of the piezoelectric plate 110. The back-side dielectric layer 216 has a thickness tbd. The front-side and back-side dielectric layers 214, 216 may be a non-piezoelectric dielectric material, such as silicon dioxide or silicon nitride. tfd and tbd may be, for example, 0 to 500 nm. tfd and tbd are typically less than the thickness ts of the piezoelectric plate. tfd and tbd are not necessarily equal, and the front-side and back-side dielectric layers 214, 216 are not necessarily the same material. Either or both of the front-side and back-side dielectric layers 214, 216 may be formed of multiple layers of two or more materials.

The IDT fingers 238 may be one or more layers of aluminum or a substantially aluminum alloy, copper or a substantially copper alloy, beryllium, titanium, tungsten, chromium, molybdenum, gold, or some other conductive material. Thin (relative to the total thickness of the conductors) layers of other metals, such as chromium or titanium, may be formed under and/or over the fingers to improve adhesion between the fingers and the piezoelectric plate 110 and/or to passivate or encapsulate the fingers. The busbars (132, 134 in FIG. 1) of the IDT may be made of the same or different materials as the fingers.

Dimension p is the center-to-center spacing or “pitch” of the IDT fingers, which may be referred to as the pitch of the IDT and/or the pitch of the XBAR. Dimension w is the width or “mark” of the IDT fingers. The IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2.5 to 10 times the width w of the fingers. In addition, the pitch p of the IDT is typically 2.5 to 25 times the thickness ts of the piezoelectric slab 212. The width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w. The thickness of the busbars (132, 134 in FIG. 1) of the IDT may be the same as, or greater than, the thickness tm of the IDT fingers.

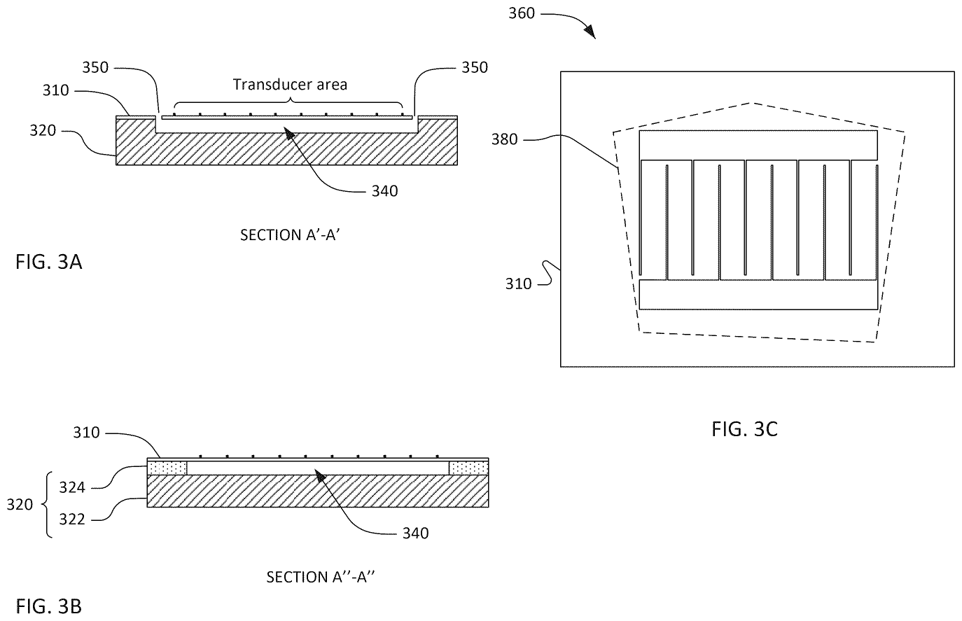

FIG. 3A and FIG. 3B show two alternative cross-sectional views along the section plane A-A defined in FIG. 1. In FIG. 3A, a piezoelectric plate 310 is attached to a substrate 320. A cavity 340, which does not fully penetrate the substrate 320, is formed in the substrate under the portion of the piezoelectric plate 310 containing the IDT of an XBAR. The cavity 340 may be formed, for example, by etching the substrate 320 before attaching the piezoelectric plate 310. Alternatively, the cavity 340 may be formed by etching the substrate 320 with a selective etchant that reaches the substrate through one or more openings 350 provided in the piezoelectric plate 310.

In FIG. 3B, the substrate 320 includes a base 322 and an intermediate layer 324 disposed between the piezoelectric plate 310 and the base 322. For example, the base 322 may be silicon and the intermediate layer 324 may be silicon dioxide or silicon nitride or some other material. A cavity 340 is formed in the intermediate layer 324 under the portion of the piezoelectric plate 310 containing the IDT of an XBAR. The cavity 340 may be formed, for example, by etching the intermediate layer 324 before attaching the piezoelectric plate 310. Alternatively, the cavity 340 may be formed by etching the intermediate layer 324 with a selective etchant that reaches the substrate through one or more openings provided in the piezoelectric plate 310.

FIG. 3C is a schematic plan view of another XBAR 360. The XBAR 360 includes an IDT formed on a piezoelectric plate 310. The piezoelectric plate 310 is disposed over a cavity 380 in a substrate. In this example, the cavity 380 has an irregular polygon shape such that none of the edges of the cavity are parallel, nor are they parallel to the conductors of the IDT. A cavity may have a different shape with straight or curved edges.

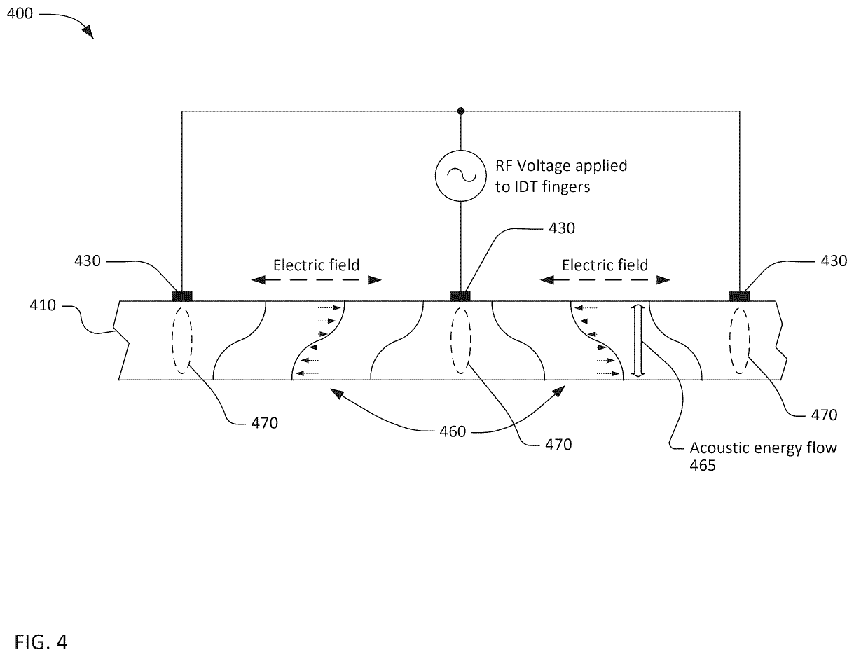

FIG. 4 is a graphical illustration of the primary acoustic mode of interest in an XBAR. FIG. 4 shows a small portion of an XBAR 400 including a piezoelectric plate 410 and three interleaved IDT fingers 430. An RF voltage is applied to the interleaved fingers 430. This voltage creates a time-varying electric field between the fingers. The direction of the electric field is lateral, or parallel to the surface of the piezoelectric plate 410, as indicated by the arrows labeled “electric field”. Due to the high dielectric constant of the piezoelectric plate, the electric field is highly concentrated in the plate relative to the air. The lateral electric field introduces shear deformation, and thus strongly excites shear-mode acoustic waves, in the piezoelectric plate 410. In this context, “shear deformation” is defined as deformation in which parallel planes in a material remain parallel and maintain a constant distance while translating relative to each other. “Shear acoustic waves” are defined as acoustic waves in a medium that result in shear deformation of the medium. The shear deformations in the XBAR 400 are represented by the curves 460, with the adjacent small arrows providing a schematic indication of the direction and magnitude of atomic motion. The degree of atomic motion, as well as the thickness of the piezoelectric plate 410, have been greatly exaggerated for ease of visualization. While the atomic motions are predominantly lateral (i.e., horizontal as shown in FIG. 4), the direction of acoustic energy flow of the excited shear acoustic waves is substantially vertical, normal to the surface of the piezoelectric plate, as indicated by the arrow 465.

Considering FIG. 4, there is essentially no electric field immediately under the IDT fingers 430, and thus acoustic modes are only minimally excited in the regions 470 under the fingers. There may be evanescent acoustic motions in these regions. Since acoustic vibrations are not excited under the IDT fingers 430, the acoustic energy coupled to the IDT fingers 430 is low (for example compared to the fingers of an IDT in a SAW resonator), which minimizes viscous losses in the IDT fingers.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

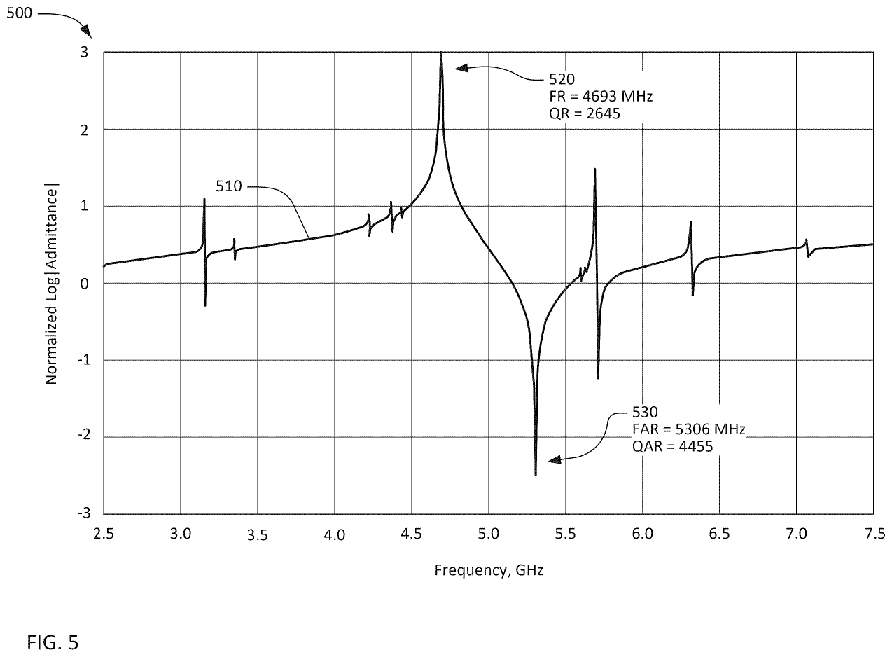

FIG. 5 is a chart 500 with a plot 510 of the normalized magnitude of the admittance (on a logarithmic scale) as a function of frequency of an XBAR simulated using finite element method (FEM) simulation techniques. In the simulated XBAR, the piezoelectric plate is Z-cut (i.e., Z axis normal to the plate) lithium niobate. The IDT fingers are aluminum. The IDT is oriented such that the y-axis of the piezoelectric plate is normal to the IDT fingers. The substrate supporting the piezoelectric plate is silicon with a cavity formed completely through the silicon (as shown in FIG. 1). Losses in the piezoelectric plate and IDT fingers were simulated using standard material parameters. The simulated physical dimensions are as follows: ts=400 nm; tfd=0; tbd=0; tm=100 nm; p=5 μm; w=500 nm. The admittance is normalized for a single pair of IDT fingers and an aperture of 1 meter. The admittance of an XBAR with N IDT fingers and an aperture A (in m) can be estimated by multiplying the normalized admittance provided in FIG. 5 by (N−1)·A.

The simulated XBAR exhibits a resonance at a frequency FR 520 of 4693 MHz and an anti-resonance at a frequency FAR 530 of 5306 MHz. The Q at resonance QR is 2645 and the Q at anti-resonance QAR is 4455. The absolute difference between FAR and FR is about 600 MHz, and the fractional difference is about 0.12. The acoustic coupling can be roughly estimated to 24%. Secondary resonances are evident in the admittance curve at frequencies below FR and above FAR.

Acoustic RF filters usually incorporate multiple acoustic resonators. Typically, these resonators have at least two different resonance frequencies. For example, an RF filter using the well-known “ladder” filter architecture includes shunt resonators and series resonators. A shunt resonator typically has a resonance frequency below the passband of the filter and an anti-resonance frequency within the passband. A series resonator typically has a resonance frequency within the pass band and an anti-resonance frequency above the passband. In many filters, each resonator has a unique resonance frequency. An ability to obtain different resonance frequencies for XBARs made on the same piezoelectric plate greatly simplifies the design and fabrication of RF filters using XBARs.

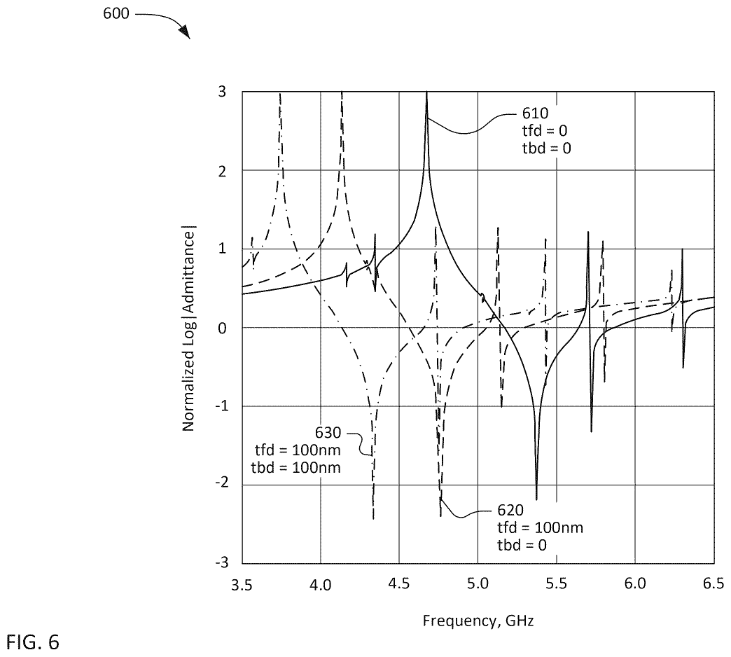

FIG. 6 is a graph 600 comparing the normalized admittances, as functions of frequency, of three XBARs with different dielectric layers. The admittance data, which is presented on a log scale, results from two-dimensional simulation of a XBAR structure using the same materials and dimensions (except for the dielectric layers) as the previous example. The admittance is normalized for a single pair of IDT fingers and an aperture of 1 m. The solid line 610 is a plot of the normalized admittance per unit aperture for an XBAR with tfd=tbd=0 (i.e., an XBAR without dielectric layers). The normalized admittance of this XBAR is comparable to the normalized admittance plot in FIG. 5, with slight differences due to the different simulation methodologies. The dashed line 620 is a plot of the normalized admittance for an XBAR with 100 nm of SiO2 on the front surface of the piezoelectric slab between the IDT fingers (tfd=100 nm and tbd=0). The addition of the SiO₂ layer on the front surface of the piezoelectric plate shifts the resonance frequency down by about 500 MHz, or about 11%, compared to the XBAR with no dielectric layers. The dash-dot line 630 is a plot of the normalized admittance for an XBAR with 100 nm of SiO₂ over the front surface of the piezoelectric slab between the IDT fingers and 100 nm of SiO₂ on the back surface of the piezoelectric slab (tfd=tbd=100 nm). The addition of the SiO₂ layers on both surfaces of the piezoelectric plate shifts the resonance frequency down by about 900 MHz, or 20%, compared to the XBAR with no dielectric layers.

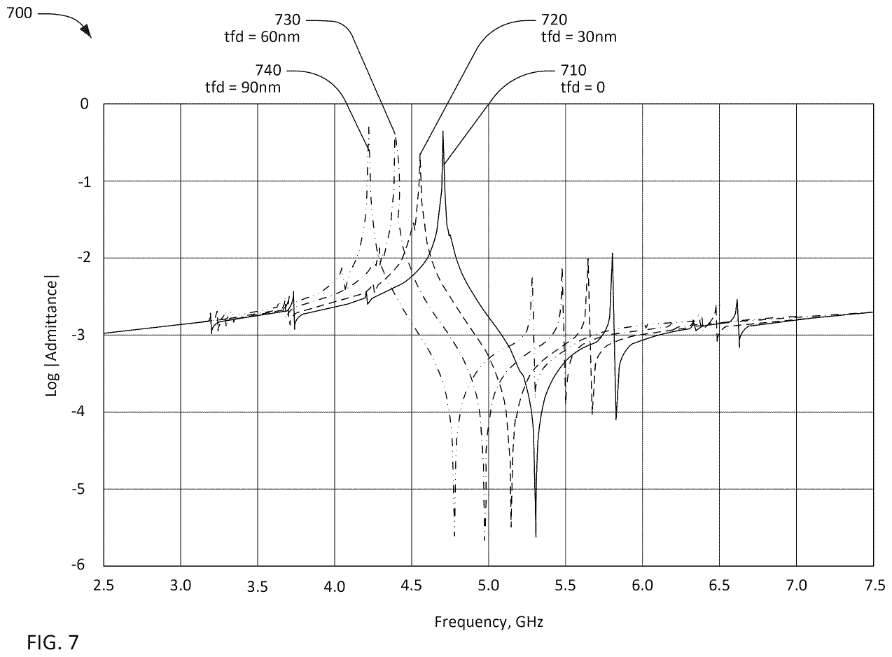

FIG. 7 is a graph 700 comparing the admittances, as functions of frequency, of four XBARs with different front-side dielectric layer thicknesses. The admittance data results from three-dimensional simulation of XBARs with the following parameter: ts=400 nm; tfd=0, 30, 60, 90 nm; tbd=0; tm=100 nm; p=4.2 μm; w=500 nm; AP=20 μm; and N (total number of IDT fingers)=51. The substrate is Z-cut lithium niobate, the IDT conductors are aluminum, and the dielectric layers are SiO2.

The solid line 710 is a plot of the admittance of an XBAR with tfd=0 (i.e., an XBAR without dielectric layers). The dashed line 720 is a plot of the admittance of an XBAR with tfd=30 nm. The addition of the 30 nm dielectric layer reduces the resonant frequency by about 145 MHz compared to the XBAR without dielectric layers. The dash-dot line 730 is a plot of the admittance of an XBAR with tfd=60 nm. The addition of the 60 nm dielectric layer reduces the resonant frequency by about 305 MHz compared to the XBAR without dielectric layers. The dash-dot-dot line 740 is a plot of the admittance of an XBAR with tfd=90 nm. The addition of the 90 nm dielectric layer reduces the resonant frequency by about 475 MHz compared to the XBAR without dielectric layers. The frequency and magnitude of the secondary resonances are affected differently than the primary shear-mode resonance.

Importantly, the presence of the dielectric layers of various thicknesses has little or no effect on the piezoelectric coupling, as evidenced by the nearly constant frequency offset between the resonance and anti-resonance of each XBAR.

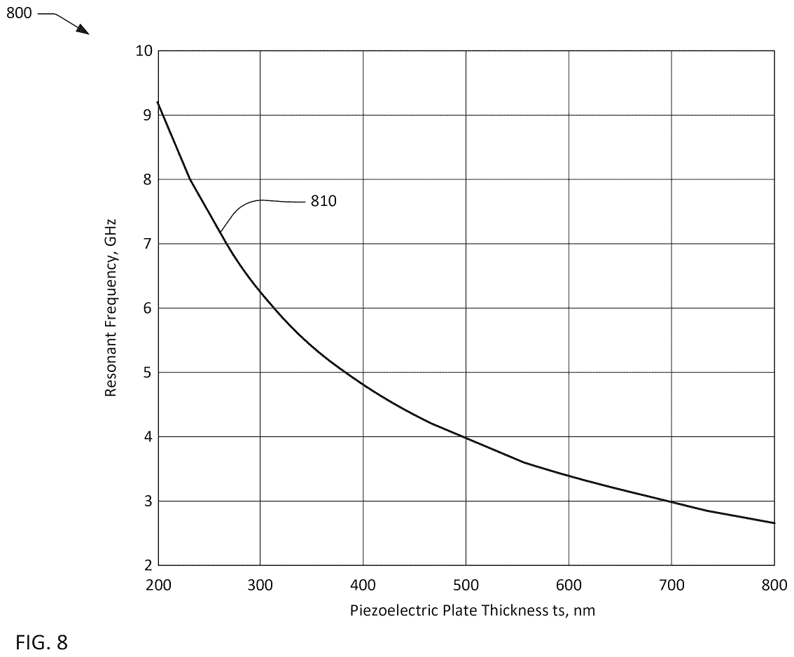

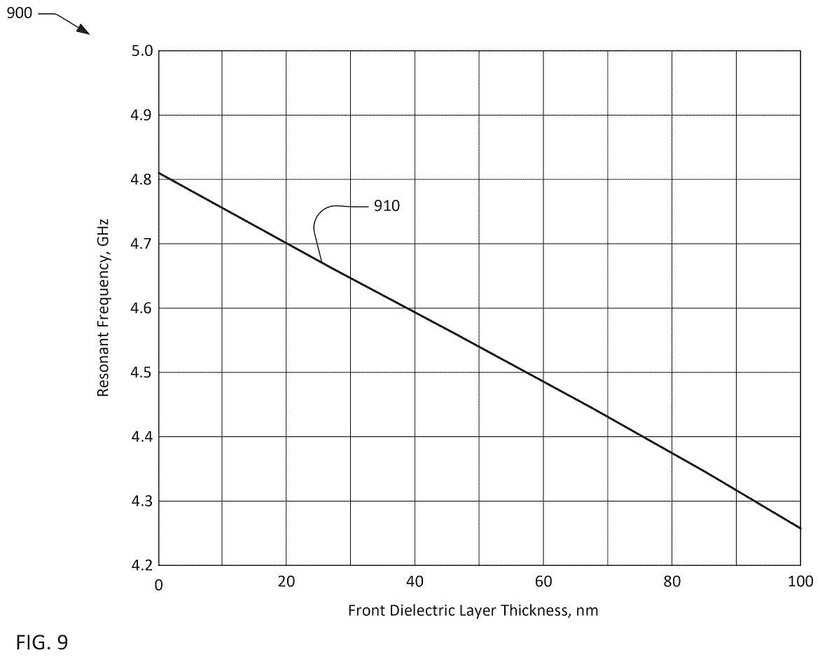

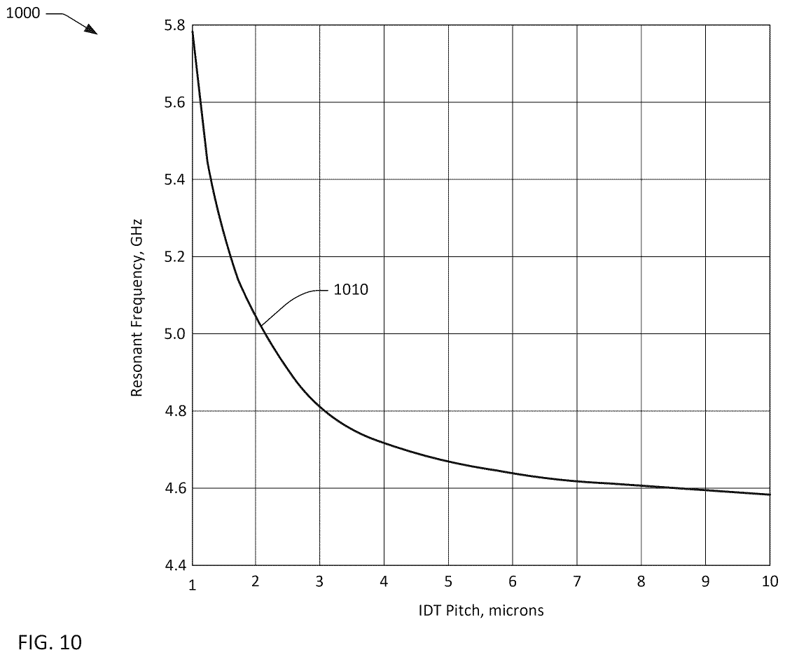

FIG. 8, FIG. 9, and FIG. 10 are graphs showing the dependence, determined by simulation, of resonant frequency on XBAR physical characteristics. Specifically, FIG. 8 is a graph 800 with curve 810 showing resonant frequency as a function of piezoelectric plate thickness ts with IDT finger pitch p=3 microns and no front-side or back-side dielectric layer (tfd=tbd=0). FIG. 9 is a graph 900 with curve 910 showing resonant frequency as a function of front-side dielectric layer thickness tfd for piezoelectric plate thickness ts=400 nm and IDT finger pitch p=3 microns. FIG. 10 is a graph 1000 with curve 1010 showing resonant frequency as a function of IDT finger pitch p with piezoelectric plate thickness ts=400 nm and tfd=tbd=0. In all cases, the piezoelectric substrate is Z-cut lithium niobate and the IDT fingers were aluminum with a width w=500 nm and thickness tm=100 nm. The front-side dielectric layer, when present, is SiO2. The range of pitch p from 1.0 to 10.0 microns is equivalent to 2.5 to 25 times the piezoelectric plate thickness and 2 to 20 time the IDT finger width.

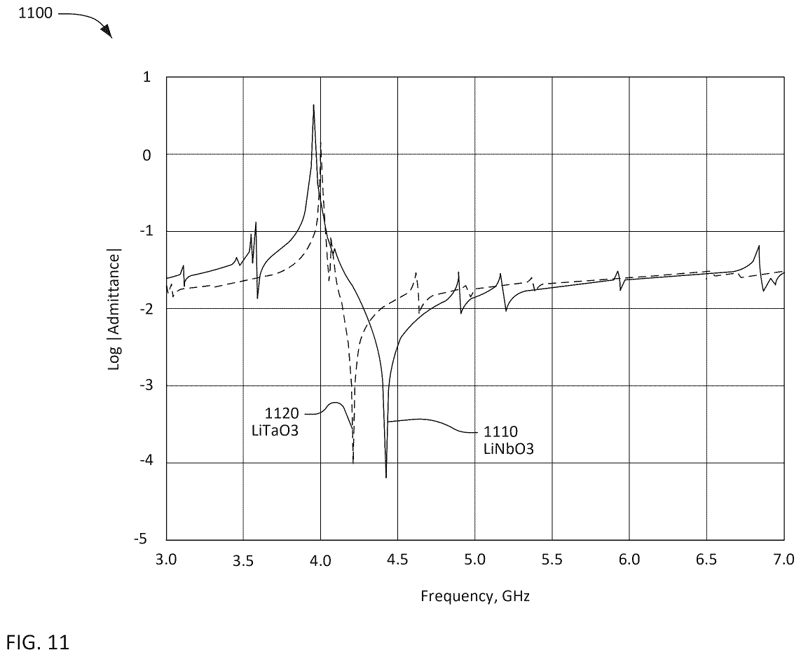

FIG. 11 is a graph 1100 comparing the admittances, as functions of frequency, of two XBARs with different piezoelectric plate materials. The admittance data results from three-dimensional simulation of XBARs with the following parameter: ts=415 nm; tfd=120 nm; tbd=0; tm=460 nm; p=4.5 μm; w=700 nm; AP=71 μm; and N (total number of IDT fingers)=221. The substrate is Z-cut lithium niobite or Z-cut lithium tantalate, the IDT electrodes are copper, and the dielectric layer is SiO2.

The solid line 1110 is a plot of the admittance of an XBAR on a lithium niobate plate. The dashed line 1120 is a plot of the admittance of an XBAR on a lithium tantalate plate. Notably, the difference between the resonance and anti-resonance frequencies of the lithium tantalate XBAR is about 5%, or half of the frequency difference of the lithium niobate XBAR.

The lower frequency difference of the lithium tantalate XBAR is due to the weaker piezoelectric coupling of the material. The measured temperature coefficient of the resonance frequency of a lithium niobate XBAR is about-71 parts-per-million per degree Celsius. The temperature coefficient of frequency (TCF) for lithium tantalate XBARs will be about half that of lithium niobate XBARs. Lithium tantalate XBARs may be used in applications that do not require the large filter bandwidth possible with lithium niobate XBARs and where the reduced TCF is advantageous.

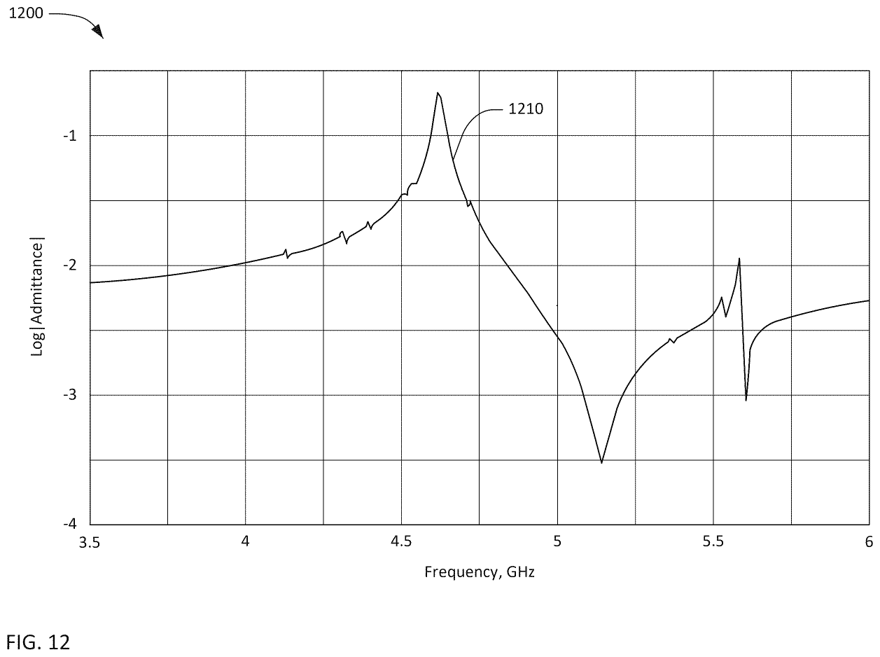

FIG. 12 is a chart 1200 showing the measured admittance of an experimental XBAR fabricated on a Z-cut lithium niobate plate with a thickness of 400 nm. The IDT had a pitch of 5 μm, an aperture of 40 μm, and 101 IDT fingers. The IDT fingers were aluminum with a thickness of 100 nm. The device did not include dielectric layers. The solid line 1210 is the magnitude of admittance as a function of frequency. The resonance frequency is 4617 MHz and the anti-resonance frequency is 5138 MHz. The frequency difference is 521 MHz or more than 11% of the resonance frequency. The measured data has not been corrected for the effects of the measurement system. Typically, correcting for the measurement system increases the anti-resonance frequency and the different between the anti-resonance and resonance frequencies.

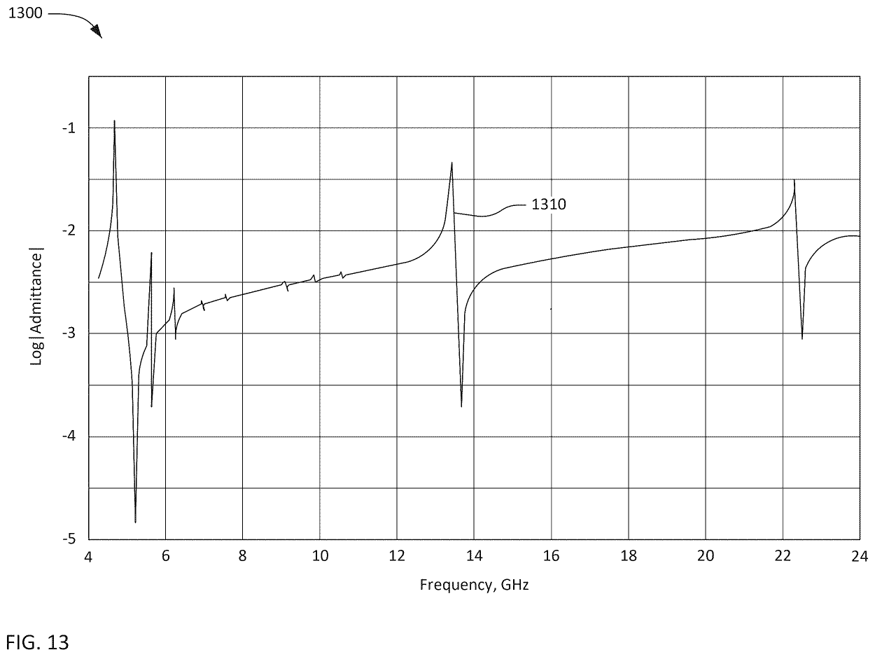

FIG. 13 is a chart 1300 showing the measured admittance of another experimental XBAR fabricated on a Z-cut lithium niobate plate with a thickness of 400 nm. The IDT had a pitch of 5 μm, an aperture of 20 μm, and 51 fingers. The IDT fingers were aluminum with a thickness of 100 nm. The device did not include dielectric layers. The solid line 1310 is the magnitude of admittance as a function of frequency. The third and fifth harmonics of the primary XBAR resonance are visible at about 13.5 GHZ and 22.5 GHZ, respectively. Resonances have been measured in other XBARs at frequencies as high as 60 GHz.

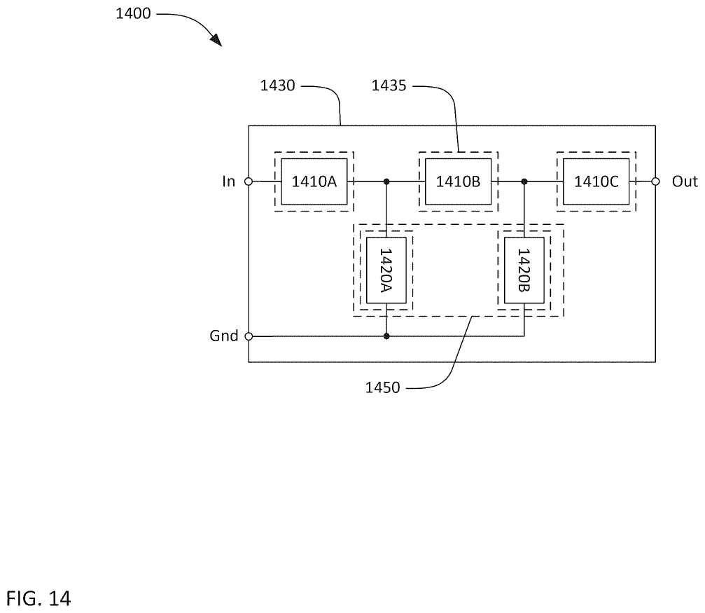

FIG. 14 is a schematic circuit diagram for a high frequency band-pass filter 1400 using XBARs. The filter 1400 has a conventional ladder filter architecture including three series resonators 1410A, 1410B, 1410C and two shunt resonators 1420A, 1420B. The three series resonators 1410A, 1410B, and 1410C are connected in series between a first port and a second port. In FIG. 14, the first and second ports are labeled “In” and “Out”, respectively. However, the filter 1400 is bidirectional and either port and serve as the input or output of the filter. The two shunt resonators 1420A, 1420B are connected from nodes between the series resonators to ground. All the shunt resonators and series resonators are XBARs.

The three series resonators 1410A, B, C and the two shunt resonators 1420A, B of the filter 1400 are formed on a single plate 1430 of piezoelectric material bonded to a silicon substrate (not visible). Each resonator includes a respective IDT (not shown), with at least the transducer area of the IDT disposed over a cavity in the substrate. In this and similar contexts, the term “respective” means “relating things each to each”, which is to say with a one-to-one correspondence. In FIG. 14, the cavities are illustrated schematically as the dashed rectangles (such as the rectangle 1435). In this example, each IDT is disposed over a respective cavity. In other filters, the IDTs of two or more resonators may be disposed over a single cavity.

In a ladder band-pass filter circuit, the anti-resonance frequencies of the series resonators 1410A, 1410B, 1410C are typically above the upper edge of the filter passband. Since each series resonator has very low admittance, approaching an open circuit, at its anti-resonance frequency, the series resonators create transmission minimums (common called “transmission zeros”) above the passband. The resonance frequencies of the shunt resonators are typically below the lower band edge of the filter pass band. Since each shunt resonator has very high admittance, approaching a short circuit, at its resonance frequency, the shunt resonators create transmission minimums (common called “transmission zeros”) below the passband.

In some broadband filters, a dielectric layer may be formed on the top side, the bottom side, or both sides of the diaphragms of the shunt resonators to lower the resonance frequencies of the shunt resonators relative to the anti-resonance frequencies of the series resonators.

In general, it is noted that for each of the ladder filter circuits described herein, one, some or all of the resonator of the circuit can be formed of a plurality of sub-resonators. For example, referring to FIG. 14, the three series resonators 1410A, B, C and the two shunt resonators 1420A, B can be composed of multiple XBAR sub-resonators connected in parallel. Dividing an XBAR into multiple (e.g., two or more) sub-resonators has a primary benefit of reducing the peak stress that would occur if each XBAR had a single large diaphragm. The multiple sub-resonators of each resonator typically, but not necessarily, have the same or substantially the same aperture and substantially the same length.

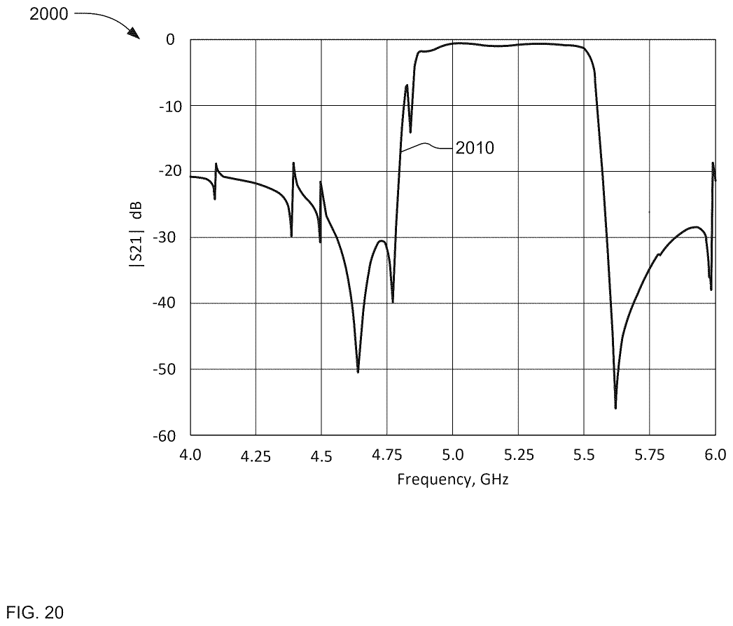

FIG. 20 is a chart 2000 showing results from simulating a first bandpass filter incorporating five XBARs. The schematic diagram of the first filter is the same as the filter 1400 of FIG. 14. The XBARs are formed on a 0.4 micron thickness Z-cut lithium niobate plate. The substrate is silicon, the IDT conductors are aluminum, and there are no dielectric layers. The other physical parameters of the resonators are provided in the following table (all dimensions are in microns):

| | Series Resonators | | | Shunt Resonators | |
|---|---|---|---|---|---|
| Parameter | 1410A | 1410B | 1410C | 1420A | 1420B |
| p | 1.475 | 1.475 | 1.525 | 3.52 | 3.52 |
| w | 0.53 | 0.53 | 0.515 | 0.51 | 0.51 |
| AP | 12.8 | 8.6 | 13.8 | 33 | 40 |
| L | 250 | 250 | 250 | 500 | 500 |

The performance of the first filter was simulated using a 3D finite element modeling tool. The curve 2010 is a plot of the magnitude of S21, the input-output transfer function, of the first filter as a function of frequency. The filter bandwidth is about 800 MHz, centered at 5.15 GHz. The simulated filter performance includes resistive and viscous losses. Tuning of the resonant frequencies of the various resonators is accomplished by varying only the pitch and width of the IDT fingers.

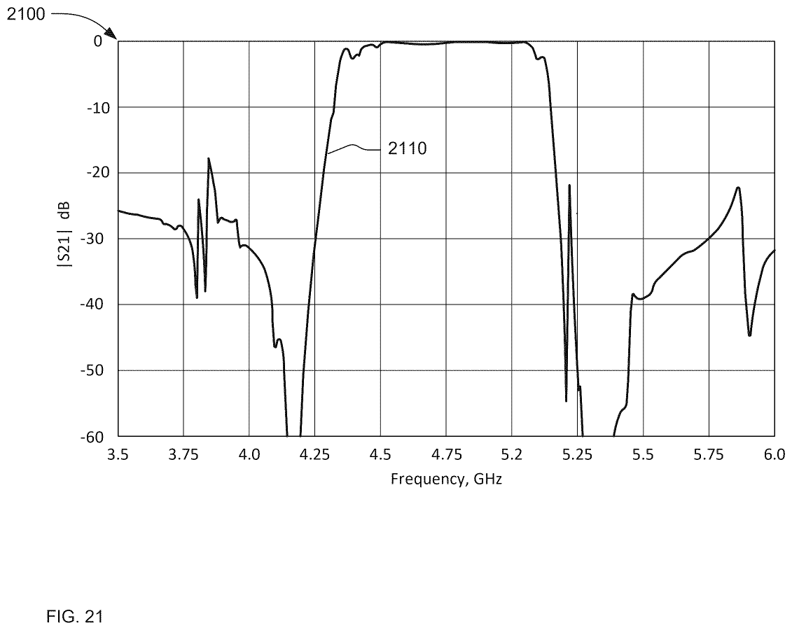

FIG. 21 is a chart 2100 showing results from simulating a second filter using five XBARs. The schematic diagram of the second filter is the same as the filter 1400 of FIG. 14. The XBARs are formed on a Z-cut lithium niobate (0.4 μm thick) piezoelectric plate. The substrate is silicon, and the IDT electrodes are copper. Adjusting the resonant frequencies of the resonators is accomplished by varying the pitch and width of the IDT fingers and by providing a frequency-setting dielectric layer on the front side between the IDT fingers of the shunt resonators to reduce their frequencies relative to the frequencies of the series resonators. The other physical parameters of the resonators are provided in the following table (all dimensions are in microns):

| | Series Resonators | | | Shunt Resonators | |
|---|---|---|---|---|---|
| Parameter | 1410A | 1410B | 1410C | 1420A | 1420B |
| p | 4.189 | 4.07 | 4.189 | 4.2 | 4.2 |
| w | 0.494 | 0.505 | 0.494 | 0.6 | 0.6 |
| AP | 46.4 | 23.6 | 46.4 | 80.1 | 80.1 |
| L | 1000 | 1000 | 1000 | 1000 | 1000 |
| tfd | 0 | 0 | 0 | 0.106 | 0.106 |

The performance of the filter was simulated using a 3D finite element modeling tool. The curve 2110 is a plot of S21, the input-output transfer function, of the simulated filter 1400 as a function of frequency. The filter bandwidth is about 800 MHz, centered at 4.75 GHz. The simulated performance does not include resistive or viscous losses.

A first dielectric layer having a first thickness may be deposited over the IDT of the shunt resonators and a second dielectric layer having a second thickness may be deposited over the IDT of the series resonators. The first thickness may be greater than the second thickness. A difference between an average resonance frequency of the series resonators and an average resonance frequency of the shunt resonators is determined, in part, by a difference between the first thickness and the second thickness.

The first and second filters (whose S21 transmission functions are shown in FIG. 21 and FIG. 21) are examples of filters using XBARs. A filter may use more or fewer than two shunt resonators, more or fewer than three series resonators, and more or fewer than five total resonators. A filter may use reactive components, such as capacitors, inductors, and delay lines in addition to XBARs. Further fine tuning of the individual resonators of these filters may improve filter performance.

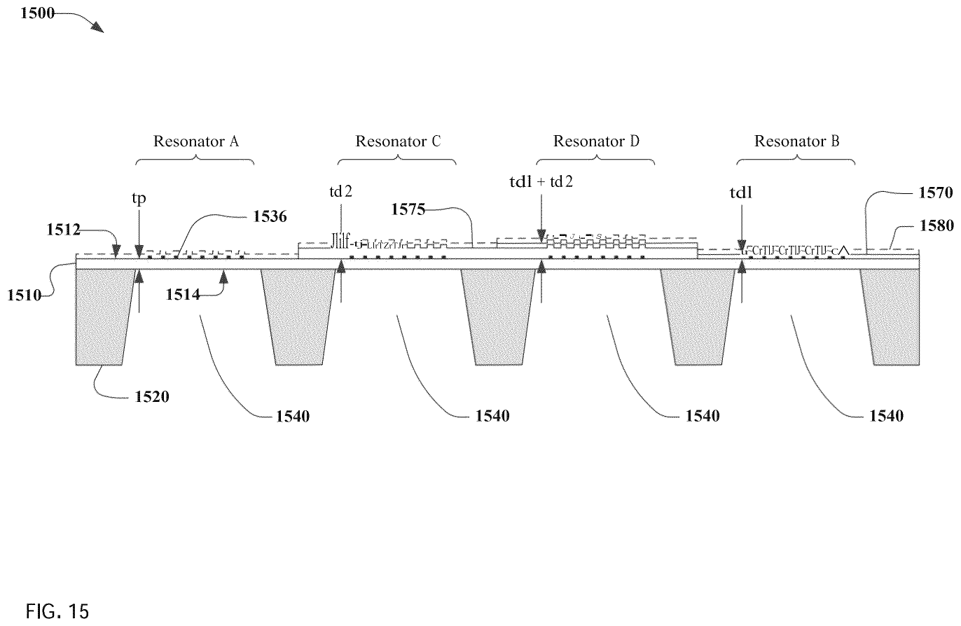

FIG. 15 is a schematic cross-sectional view of an improved XBAR filter 500 that uses multiple frequency setting layers. The filter 1500 includes four XBARs identified as Resonator A, Resonator B, Resonator C, and Resonator D. All four resonators are formed on a piezoelectric plate 1510 attached to a substrate 1520. Portions of the piezoelectric plate 1510 are suspended over four cavities 1540 formed in the substrate. While the four cavities 1540 are shown extending through the substrate 1520, the cavities may only extend through a portion of the thickness of the substrate as shown in FIG. 3A. Each of the four resonators A-D includes respective IDT fingers, such as IDT finger 1536 of resonator A, disposed on the top surface 1512 of the piezoelectric plate over the respective cavities.

Resonator A does not include a dielectric frequency setting layer. In this case, the thickness of the diaphragm of resonator A is equal to the thickness tp of the piezoelectric plate 1510. Resonator B has a first frequency setting layer 1570 formed over the IDT fingers 1530. The thickness of the diaphragm of resonator B is equal to tp plus the thickness td1 of the first frequency setting layer. Resonator C has a second frequency setting layer 1575 formed over the IDT fingers 1530. The thickness of the diaphragm of resonator C is equal to tp plus the thickness td2 of the second frequency setting layer. The thickness td2 of the second frequency setting layer is greater than the thickness td1 of the first frequency setting layer. Resonator D includes both the first frequency setting layer 1570 and the second frequency setting layer 1575. The thickness of the diaphragm of resonator D is equal to tp+td1+td2. Since the resonant frequency of an XBAR is highly dependent on diaphragm thickness, the following relationships will usually hold:

$${f}_{A} > {f}_{B} > {f}_{C} > {f}_{D} ,$$

where f_{A}, f_{B}, f_{C}, and f_{D} are the resonance frequencies of resonators A-D, respectively.

The first frequency setting layer 1570 and the second frequency setting layer 1575 may be silicon dioxide, silicon nitride, silicon oxynitride, aluminum oxide, or some other dielectric material with low acoustic loss. The first frequency setting layer 1570 and the second frequency setting layer 1575 are typically, but not necessarily, the same material. All or portions of the first frequency setting layer 1570 and/or the second frequency setting layer 1575 may be formed on the back surface 1514 of the piezoelectric plate 1510.

An optional thin dielectric passivation layer 1580 (shown in dashed lines) may be applied over all of the resonators. If present, the thickness of the passivation layer 1580 may be comparable to or less than the thickness td1 of the first frequency setting layer 1570.

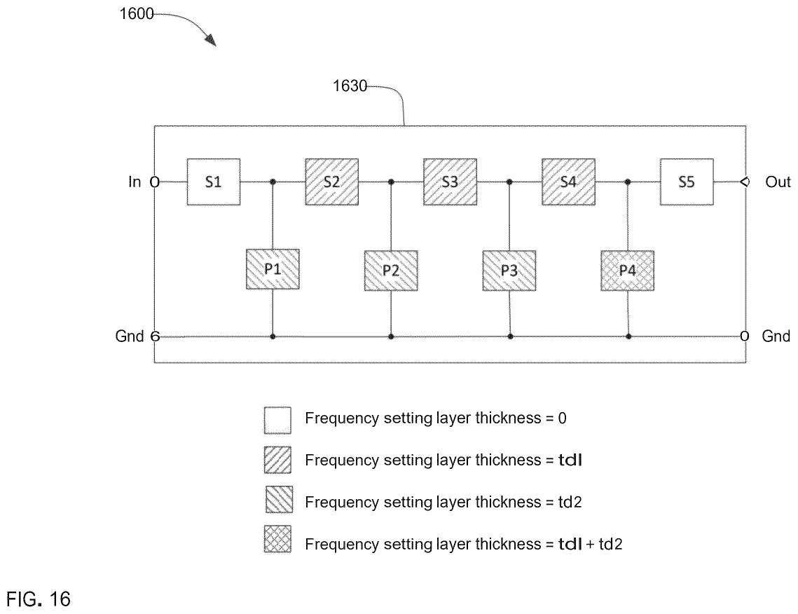

FIG. 16 is a block diagram of a bandpass filter 1600 including five series resonators S1, S2, S3, S4, and S5 and four shunt (parallel) resonators P1, P2, P3, P4 that can be formed on a single plate 1630 of piezoelectric material bonded to a silicon substrate (not visible) in an exemplary aspect. The bandpass filter 600 is fabricated with two frequency setting layers. A first frequency setting layer having thickness td1 is provided on series resonators S2, S3, and S4 and shunt resonator P4. A second frequency setting layer having thickness td2, which is greater than td1, is provided on the shunt resonators P1 to P4. Series resonators S1 and S5 do not have a frequency setting layer. Shunt resonator P4 has both frequency setting layers.

The structure of series resonators S1 and S5 will be similar to that of Resonator A in FIG. 15. The structure of series resonators S2, S3 and S4 will be similar to that of Resonator B in FIG. 15. The structure of shunt resonators P1, P2, and P3 will be similar to that of Resonator C in FIG. 15. The structure of shunt resonator P4 will be similar to that of Resonator D in FIG. 15.

The inclusion of five series resonators and four shut resonators in the filter 1600 is exemplary, as is the number of resonators that have none, one, or both of the frequency setting layers. In general, the first frequency setting layer will be formed over a first subset of the total number of resonators and the second frequency setting layer will be formed over a second subset of the total number of resonators. In this context, the word “subset” has its conventional meaning of “some but not all”. The first and second subsets will not be identical. One or more resonators (e.g., resonator P4 in this example) may belong to both subsets and thus receive both the first and second frequency setting layers. One or more resonators (S1 and S5 in this example) may not belong to either subset. In addition to the first and second frequency setting layers, a passivation layer may be applied over all resonators.

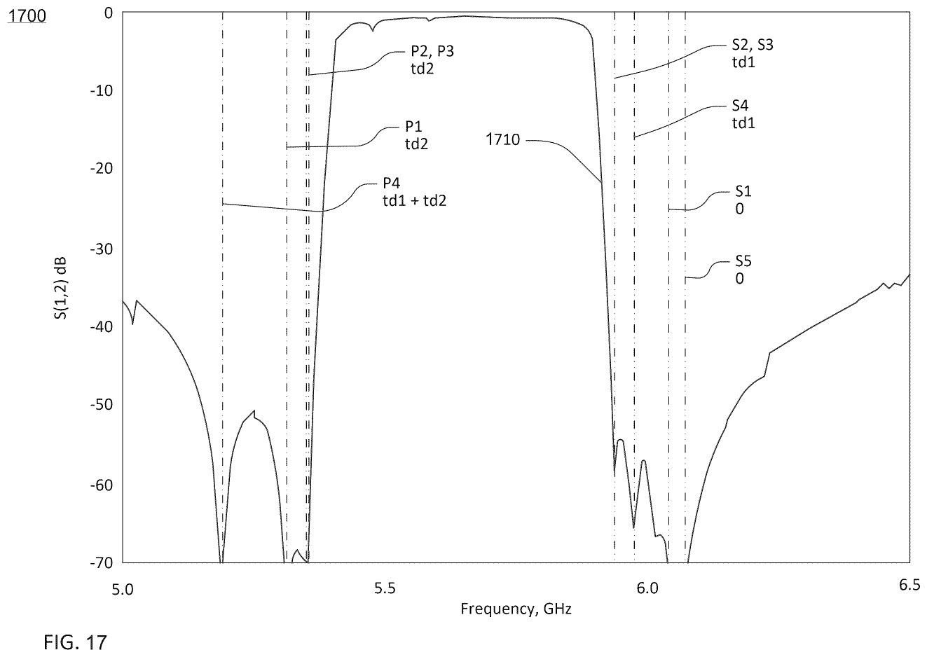

FIG. 17 is a chart showing results from simulating an embodiment of the filter of FIG. 16. The performance of the filter was simulated using a 3D finite element modeling tool. The curve 1710 is a plot of the magnitude of S21, the input-output transfer function, of the filter as a function of frequency. The dot-dash vertical lines represent the transmission zeros at or near the resonance frequencies of the shunt resonators P1, P2, P3, and P4. The dot-dot-dash vertical lines represent the transmission zeros at or near the anti-resonance frequencies of the series resonators S1 to S5. Each of these lines is labeled with the corresponding resonator designator and the thickness of the respective frequency setting dielectric layer.

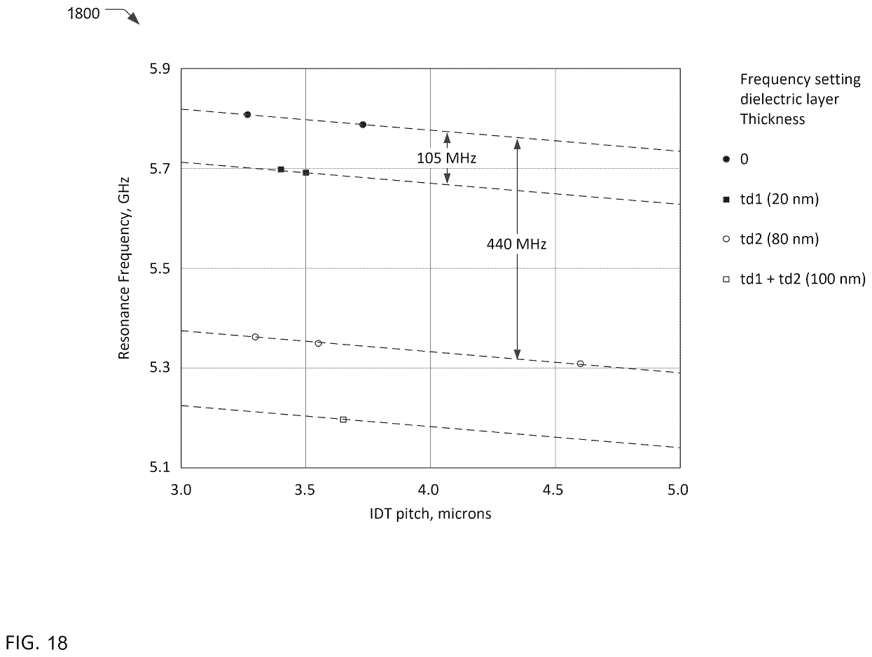

The effect of frequency setting dielectric layers can be understood through consideration of FIG. 18. FIG. 18 is a graph 1800 of the resonance frequencies of the XBARs in the filter 1600 of FIG. 16 as a function of IDT pitch. Solid circles represent resonators without a frequency setting dielectric layer. Solid squares represent resonators with the first frequency setting dielectric layer with thickness td1. Open circles represent resonators with the second frequency setting dielectric layer with thickness td2. The open square represents the resonator with both the first and second frequency setting dielectric layers with a total thickness of td1+td2. In this example td1=20 nm and td2=80 nm. The dashed lines represent the approximate relationships between resonance frequency and IDT pitch for the various dielectric layer thicknesses.

Resonance frequency has a roughly linear dependence on IDT pitch for the IDT pitch range of 3 to 5 microns. However, the dependence is weak, with a 50% change in IDT pitch resulting in roughly 2% change in resonance frequency. Resonance frequency has a stronger dependence on frequency setting dielectric layer thickness. For resonators having the same IDT pitch, the first frequency dielectric layer lowers resonance frequency by about 105 MHz compared to resonators with no dielectric layer. For resonators having the same IDT pitch, the second frequency dielectric layer lowers resonance frequency by about 440 MHz compared to resonators with no dielectric layer.

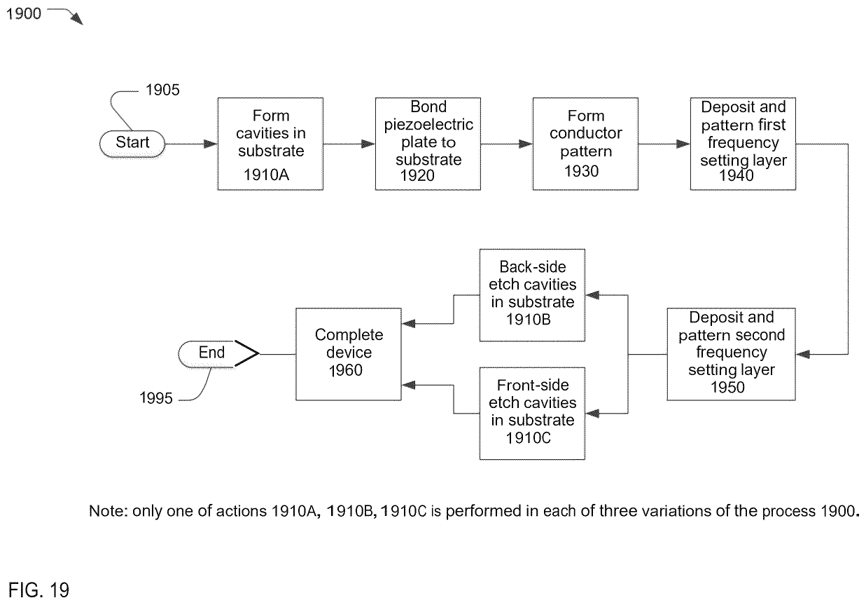

FIG. 19 is a simplified flow chart showing a process 1900 for making an XBAR or a filter incorporating XBARs. The process 1900 starts at 1905 with a substrate and a plate of piezoelectric material and ends at 1995 with a completed XBAR or filter. The flow chart of FIG. 19 includes only major process steps. Various conventional process steps (e.g., surface preparation, cleaning, inspection, baking, annealing, monitoring, testing, etc.) may be performed before, between, after, and during the steps shown in FIG. 19.

The flow chart of FIG. 19 captures three variations of the process 1900 for making an XBAR which differ in when and how cavities are formed in the substrate. The cavities may be formed at steps 1910A, 1910B, or 1910C. Only one of these steps is performed in each of the three variations of the process 1900.

The piezoelectric plate may be, for example, Z-cut lithium niobate or lithium tantalate as used in the previously presented examples. The piezoelectric plate may be some other material and/or some other cut. The substrate may preferably be silicon. The substrate may be some other material that allows formation of deep cavities by etching or other processing.

In one variation of the process 1900, one or more cavities are formed in the substrate at 1910A before the piezoelectric plate is bonded to the substrate at 1920. A separate cavity may be formed for each resonator in a filter device. The one or more cavities may be formed using conventional photolithographic and etching techniques. Typically, the cavities formed at 1910A will not penetrate through the substrate, and the resulting resonator devices will have a cross-section as shown in FIG. 3A.

At 1920, the piezoelectric plate is bonded to the substrate. The piezoelectric plate and the substrate may be bonded by a wafer bonding process. Typically, the mating surfaces of the substrate and the piezoelectric plate are highly polished. One or more layers of intermediate materials, such as an oxide or metal, may be formed or deposited on the mating surface of one or both of the piezoelectric plate and the substrate. One or both mating surfaces may be activated using, for example, a plasma process. The mating surfaces may then be pressed together with considerable force to establish molecular bonds between the piezoelectric plate and the substrate or intermediate material layers. The piezoelectric plate may be bonded to the substrate using some other technique.

A conductor pattern, including IDTs of each XBAR in the filter, is formed at 1930 by depositing and patterning one or more conductor layers on the front side of the piezoelectric plate. The conductor layer may be, for example, aluminum, an aluminum alloy, copper, a copper alloy, or some other conductive metal. Optionally, one or more layers of other materials may be disposed below (i.e., between the conductor layer and the piezoelectric plate) and/or on top of the conductor layer. For example, a thin film of titanium, chrome, or other metal may be used to improve the adhesion between the conductor layer and the piezoelectric plate. A conduction enhancement layer of gold, aluminum, copper or other higher conductivity metal may be formed over portions of the conductor pattern (for example the IDT bus bars and interconnections between the IDTs).

The conductor pattern may be formed at 1930 by depositing the conductor layer and, optionally, one or more other metal layers in sequence over the surface of the piezoelectric plate. The excess metal may then be removed by etching through patterned photoresist. The conductor layer can be etched, for example, by plasma etching, reactive ion etching, wet chemical etching, and other etching techniques.

Alternatively, the conductor pattern may be formed at 1930 using a lift-off process. Photoresist may be deposited over the piezoelectric plate and patterned to define the conductor pattern. The conductor layer and, optionally, one or more other layers may be deposited in sequence over the surface of the piezoelectric plate. The photoresist may then be removed, which removes the excess material, leaving the conductor pattern.

At 1940, the first frequency setting dielectric layer may be formed by depositing a dielectric material on the front side of the piezoelectric plate. The first frequency setting dielectric layer may be deposited using a conventional deposition technique such as atomic layer deposition, physical vapor deposition, or chemical vapor deposition. One or more lithography processes (using photomasks) may be used to limit the first frequency setting dielectric layer to selected areas of the piezoelectric plate, such as only over the fingers of a first subset of IDTs. The thickness of the first frequency setting dielectric layer is td1.

At 1950, the second frequency setting dielectric layer may be formed by depositing a dielectric material on the front side of the piezoelectric plate. The second frequency setting dielectric layer may be deposited using a conventional deposition technique such as atomic layer deposition, physical vapor deposition, or chemical vapor deposition. One or more lithography processes (using photomasks) may be used to limit the second frequency setting dielectric layer to selected areas of the piezoelectric plate, such as only over the fingers of a second subset of IDTs. The thickness of the second frequency setting dielectric layer is td2. Typically, td2>td1.

In a second variation of the process 1900, one or more cavities are formed in the back side of the substrate at 1910B. A separate cavity may be formed for each resonator in a filter device. The one or more cavities may be formed using an anisotropic or orientation-dependent dry or wet etch to open holes through the back side of the substrate to the piezoelectric plate. In this case, the resulting resonator devices will have a cross-section as shown in FIG. 1.

In a third variation of the process 1900, one or more cavities in the form of recesses in the substrate may be formed at 1910C by etching the substrate using an etchant introduced through openings in the piezoelectric plate. A separate cavity may be formed for each resonator in a filter device. The one or more cavities formed at 1910C will not penetrate through the substrate, and the resulting resonator devices will have a cross-section as shown in FIG. 3A.

In all variations of the process 1900, the filter device is completed at 1960. Actions that may occur at 1960 include depositing an encapsulation/passivation layer such as silicon oxide or silicon nitride over all or a portion of the device; forming bonding pads or solder bumps or other means for making connection between the device and external circuitry; excising individual devices from a wafer containing multiple devices; other packaging steps; and testing. Another action that may occur at 1960 is to tune the resonant frequencies of the resonators within the device by adding or removing metal or dielectric material from the front side of the device. After the filter device is completed, the process ends at 1995.

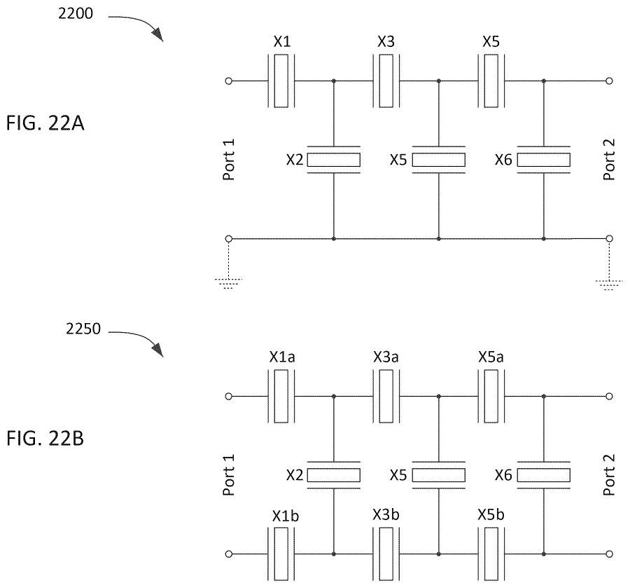

FIG. 22A shows a simplified schematic circuit diagram of an exemplary RF filter circuit 2200 incorporating six acoustic wave resonators, labeled X1 through X6, arranged in what is commonly called a “ladder” configuration. A ladder filter of this configuration is commonly used for band-pass filters in communications devices. The filter circuit 2200 may be, for example, a transmit filter or a receive filter for incorporation into a communications device. The filter circuit 2200 is a two-port network where one terminal of each port is typically connected to a signal ground. The filter circuit 2200 includes three series resonators (X1, X3, and X5) connected in series between a first port (Port 1) and second port (Port 2). Either port may be the input to the filter, with the other port being the output. The filter circuit 2200 includes three shunt resonators (X2, X4, and X6). Each shunt resonator is connected between ground and either a junction of adjacent series resonators or the input or output port. The schematic diagram of FIG. 22A is simplified in that passive components, such as the inductances inherent in the conductors interconnecting the resonators, are not shown. The use of six acoustic wave resonators, three series resonators, and three shunt resonators is exemplary. A band-pass filter circuit may include more than, or fewer than, six resonators and more than, or fewer than, three series resonators and three shunt resonators.

FIG. 22B shows a simplified schematic circuit diagram of an alternative RF filter circuit 2250. The filter circuit 2250 is a two-port network where the signals at each port are balanced, which is to say the signal at the two terminals of each port are nominally equal in amplitude and separated by 180 degrees in phase. For the purposes of this patent, the RF filter circuit 2250 is considered a ladder filter. The resonators X1a, X1b, X3a, X3b, X5a, and X5b are considered series resonators, and the resonators X2, X4, and X6 are considered shunt resonators. The ladder filter circuit 2250 is not commonly used and all of the subsequent examples in this patent assume the ladder filter configuration of FIG. 22A.

Each acoustic wave resonator X1 to X6 may be a bulk acoustic wave (BAW) resonator, a film bulk acoustic wave (FBAW) resonator, a surface acoustic wave (SAW) resonator, a temperature compensated surface acoustic wave resonator (TC-SAW), a bonded wafer acoustic resonator, a transversely-excited film bulk acoustic resonator (XBAR) as described in application Ser. No. 16/230,443, a solidly-mounted transversely-excited film bulk acoustic resonator (SM-XBAR) as described in application Ser. No. 16/438,141, or some other type of acoustic wave resonator. In current filters of the acoustic wave resonators are typically the same type of resonator.

Each acoustic wave resonator exhibits very high admittance at a resonance frequency and very low admittance at an anti-resonance frequency higher than the resonance frequency. In simplified terms, each resonator is approximately a short circuit at its resonance frequency and an open circuit at its anti-resonance frequency. Thus, the transmission between Port 1 and Port 2 of the band-pass filter circuits 2200 and 2250 is very low at the resonance frequencies of the shunt resonators and the anti-resonance frequencies of the series resonators. In a typical ladder band-pass filter, the resonance frequencies of shunt resonators are less than a lower edge of the filter passband to create a stopband at frequencies below the passband. The anti-resonance frequencies of shut resonators typically fall within the passband of the filter. Conversely, the anti-resonance frequencies of series resonators are greater than an upper edge of the passband to create a stopband at frequencies above the passband. The resonance frequencies of series resonators typically fall within the passband of the filter. In some designs, one or more shunt resonators may have resonance frequencies higher than the upper edge of the passband.

A filter device, such as the band-pass filter circuits 2200 and 2250, including acoustic wave resonators is traditionally implemented using multiple layers of materials deposited on, bonded to, or otherwise formed on a substrate. The substrate and the sequence of material layers are commonly referred to as the “stack” used to form the acoustic wave resonators and the filter device. In this patent, the term “material stack” means an ordered sequence of material layers formed on a substrate, where the substrate is considered a part of the material stack. The term “element” means the substrate or one of the layers in a material stack. At least one element in the material stack (i.e. either the substrate or a layer) is a piezoelectric material such as quartz, lithium niobate, lithium tantalate, lanthanum gallium silicate, gallium nitride, or aluminum nitride. When the piezoelectric material is a single crystal, the orientations of the X, Y, and Z crystalline axes are known and consistent. One or more layers in the material stack, such as one or more conductor layers and/or dielectric layers, may be patterned using photolithographic methods, such that not all elements of the material stack are present at every point on the acoustic wave device.

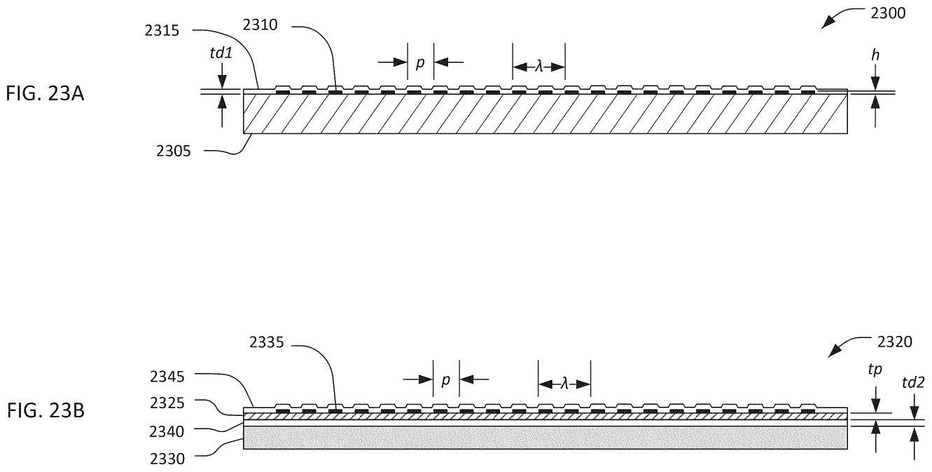

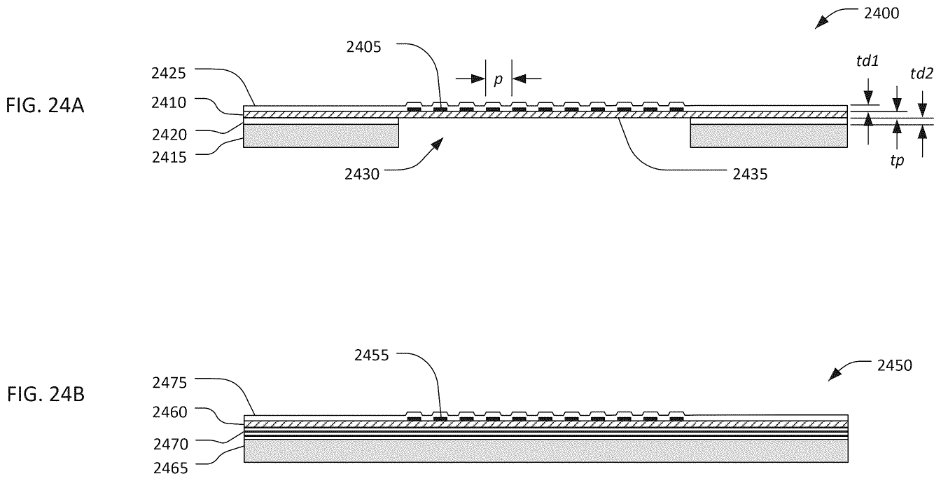

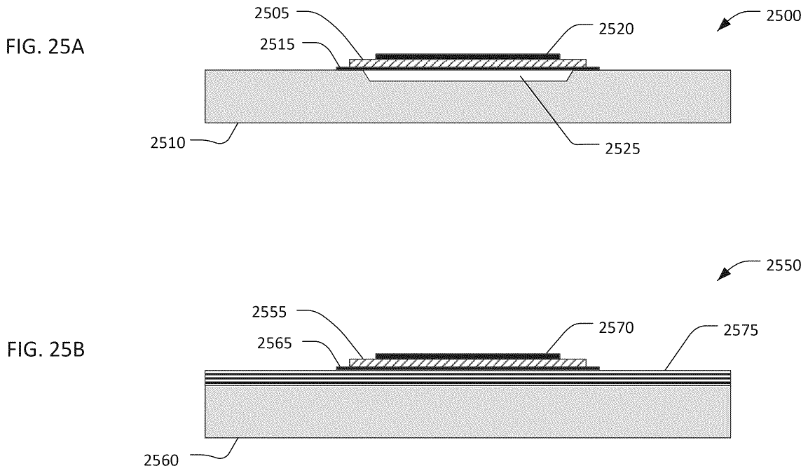

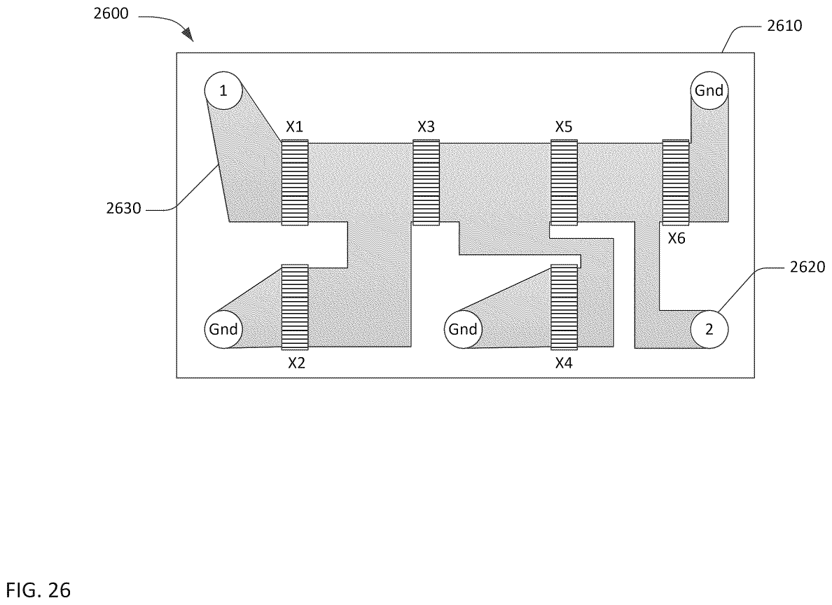

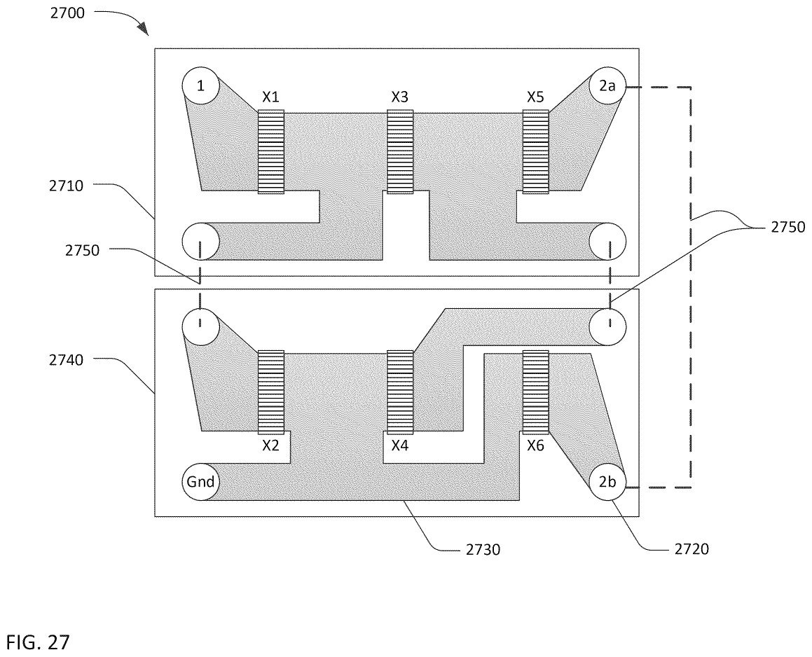

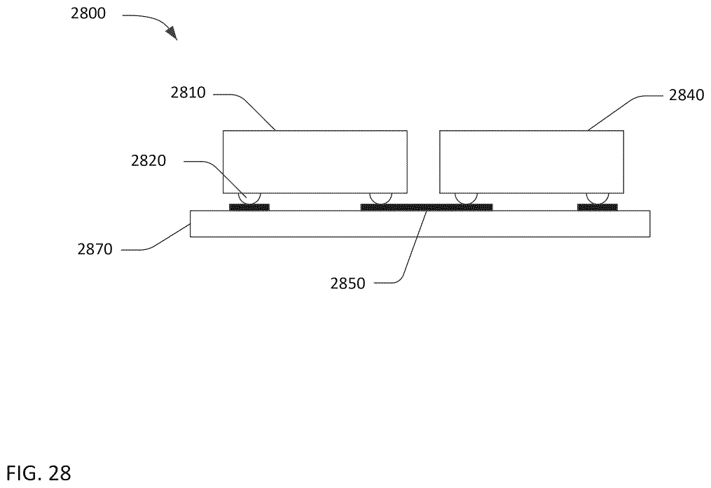

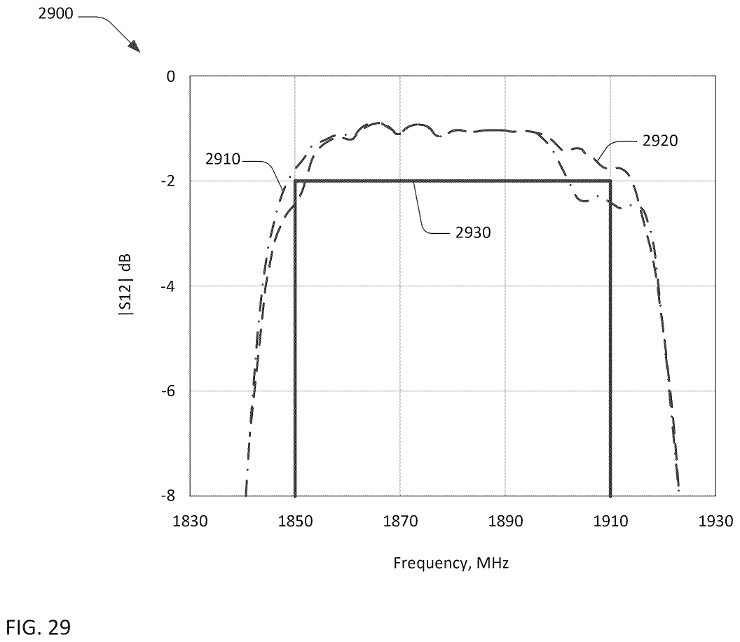

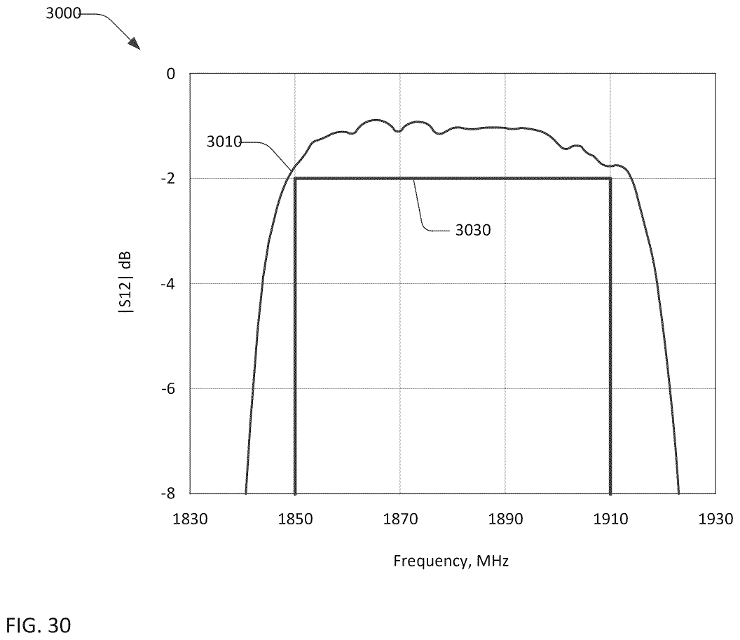

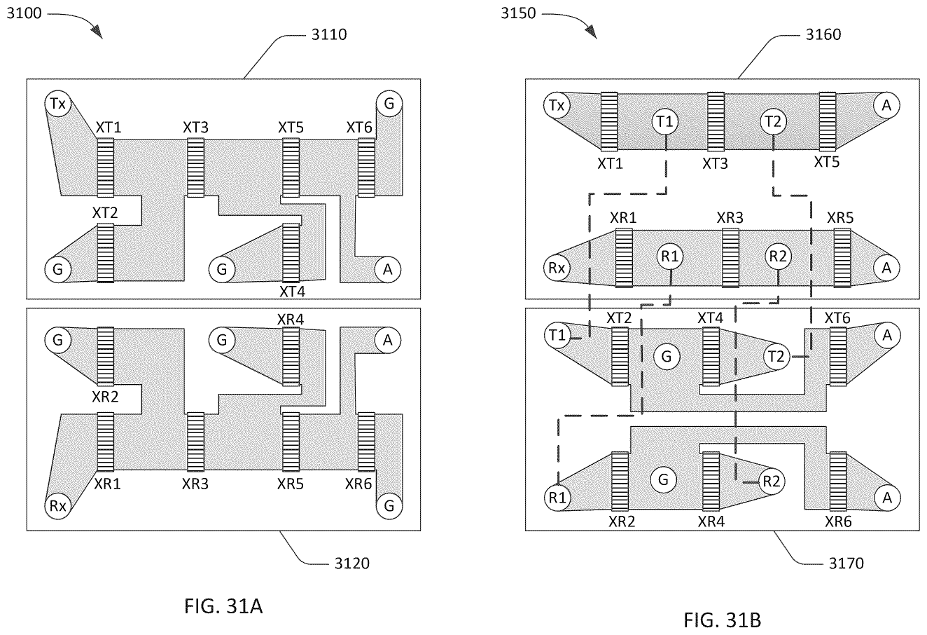

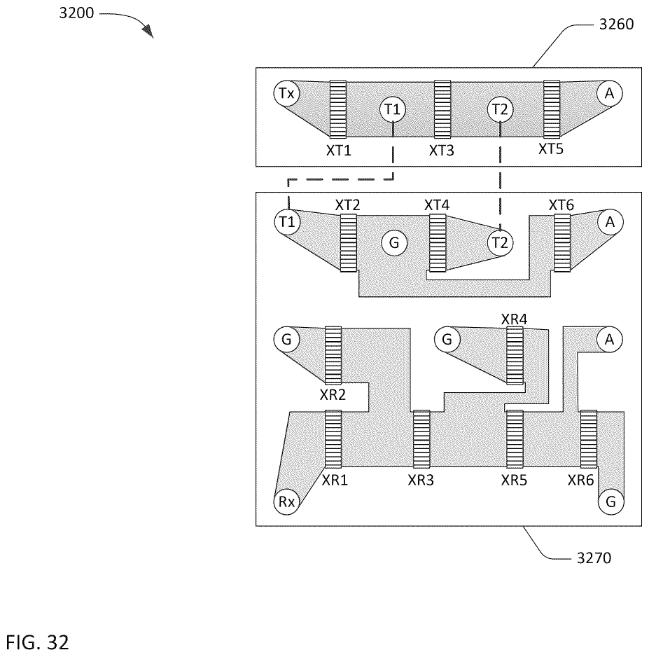

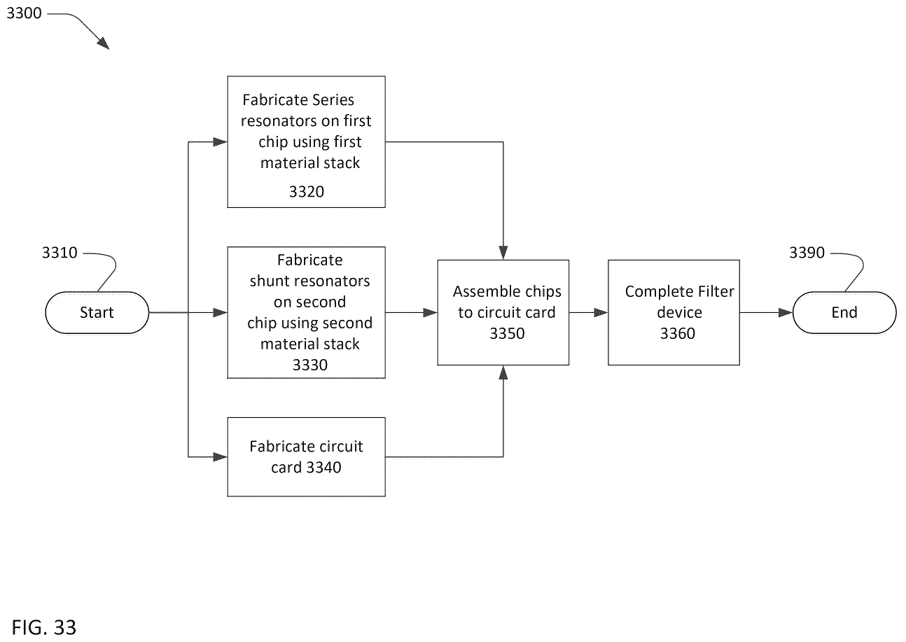

FIG. 23A is a schematic cross-section view of first exemplary acoustic wave resonator 2300. The first acoustic wave resonator 2300 will be referred to herein as a “non-bonded SAW resonator” (as opposed to a “bonded-wafer resonator to be described in conjunction with FIG. 23B). A “non-bonded SAW resonator” is characterized by a conductor pattern 2310 formed on a piezoelectric plate 2305 that is not bonded to a thicker base or substrate. This term encompasses both temperature-compensated and non-temperature compensated SAW resonators. The conductor pattern 2310 including an interdigital transducer (IDT) formed on a surface of the plate 2305 of single-crystal piezoelectric material. Dimension p is the pitch, or conductor-to-conductor spacing, of the fingers of the IDT. The dimension λ=2p is the wavelength of the acoustic wave that propagates across the surface of the piezoelectric plate 2305. When multiple non-bonded SAW resonators 2300 are combined to form a filter device, the resonance frequencies of various resonators are set by selecting the pitch of each resonator. The dimension h is the thickness of the conductor pattern. A dielectric layer 2315, having a thickness td1, may be deposited over and between the conductors of the conductor pattern. The dielectric layer 2315 may be, for example, a thin passivation layer to seal and protect the electrode pattern and the surface of the piezoelectric plate 2305. In a TC-SAW resonator, the dielectric layer 2315 may be a relatively thick layer of, for example, SiO2 used to reduce the temperature coefficient of frequency of the resonator.

The material stack for a non-bonded SAW resonator, such as the first exemplary acoustic wave resonator 2300, includes the piezoelectric plate 2305, the conductor pattern 2310 and the dielectric layer 2315. The piezoelectric plate 2305 is defined by a material type, thickness, and orientation of the crystalline axes of the piezoelectric material. The conductor pattern 2310 is defined by the thickness h and material, which may be, for example, aluminum, copper, gold, molybdenum, tungsten, and alloys and combinations thereof. The dielectric layer 2315 is defined by the thickness td1 and material, which may be, for example, silicon dioxide or silicon nitride. When multiple non-bonded SAW resonators 2300 are incorporated into a filter device, the material stack may include additional layers not shown in FIG. 23A. For example, filter devices commonly include a second metal layer to increase the conductivity of conductors interconnecting the resonators, and may include additional dielectric layers and/or a third metal layer of thick gold or solder to form bumps to interconnect the filter with an external circuit card.

FIG. 23B is a schematic cross-section view of a second exemplary acoustic wave resonator 2320. The second acoustic wave resonator 2320 will be referred to herein as a “bonded-wafer resonator.” A “bonded-wafer resonator” is characterized by a thin wafer or plate 2325 of single-crystal piezoelectric material bonded to a non-piezoelectric base 2330. The thin wafer or plate 2325 of single-crystal piezoelectric material may be bonded to the non-piezoelectric base 2330 directly, or indirectly by means of one or more intermediate dielectric layers 2340. The second acoustic wave resonator 2320 may be, for example, a bonded-wafer SAW resonator, an IHP (Incredibly High Performance) SAW resonator, or a plate wave resonator. The second acoustic wave resonator 2320 includes a conductor pattern 2335 including an IDT formed on a surface of the thin wafer 2325 of single-crystal piezoelectric material. The thickness of the conductor pattern is dimension h (see FIG. 23A). Dimension tp is the thickness of the wafer 2325 of piezoelectric material. Dimension p is the pitch, or conductor-to-conductor spacing, of the fingers of the IDT. The dimension λ=2p is the wavelength of the acoustic wave that propagates across the surface of or within the piezoelectric wafer 2325. When multiple bonded-wafer resonators 2320 are combined to form a filter device, the resonance frequencies of various resonators are set by selecting the IDT pitch of each resonator. A dielectric layer 2345 of thickness td1 (see FIG. 23A) may be deposited over and between the conductors of the conductor pattern as previously described. A second dielectric layer 2340, having a thickness td2, may be disposed between the wafer 2325 and the base 2330. In some cases, two dielectric layers may be disposed between the wafer 2325 and the base 2330.

The material stack for a bonded-wafer resonator, such as the second exemplary acoustic wave resonator 2320, includes the base 2330, the underlying dielectric layer or layers 2340, if present, the piezoelectric wafer 2325, the conductor pattern 2335 and the dielectric layer 2345. The base 2330 is defined by a material and thickness. The underlying dielectric layers 2340 are defined by a material type and thickness td2 of each layer. The piezoelectric wafer 2325 is defined by a material type, thickness tp, and orientation of the crystalline axes of the piezoelectric material. The conductor pattern 2335 is defined by the thickness h (See FIG. 23A) and material. The dielectric layer 2345 is defined by the thickness td1 and material. When multiple bonded-wafer resonators 2320 are incorporated into a filter, the material stack may include additional layers as previously described.

FIG. 24A is a schematic cross-section view of a third exemplary acoustic wave resonator 2400. The third acoustic wave resonator 2400 will be referred to herein as a “floating-diaphragm resonator”. A floating diaphragm resonator is characterized by a thin diaphragm 2435 of single-crystal piezoelectric material floating over a cavity 2430 formed in a non-piezoelectric base 2415. The third acoustic wave resonator 2400 may be, for example, an XBAR resonator as described in application Ser. No. 16/230,443 or some other type of acoustic resonator. The third acoustic wave resonator 2400 includes a conductor pattern 2405 including an IDT formed on a surface of a thin wafer 2410 of single-crystal piezoelectric material, which is attached or bonded to the non-piezoelectric base 2415. When the third acoustic wave resonator is a plate wave resonator, the conductor pattern may include Bragg reflectors (not shown in FIG. 24A). A dielectric layer 2420 or layers may be present between the wafer 2410 and the base 2415. The cavity 2430 is formed in the base 2415 and dielectric layer(s) 2420, if present, such that a portion of the wafer 2410 forms the diaphragm 2435 spanning the cavity 2430. The fingers of the IDT are disposed on the diaphragm 2435. A dielectric layer 2425 may be deposited over and between the fingers of the conductor pattern 2405.

The material stack for a floating diaphragm resonator, such as the third exemplary acoustic wave resonator 2400, includes the base 2415, the underlying dielectric layer or layers 2420, if present, the piezoelectric wafer 2410, the conductor pattern 2405 and the dielectric layer 2425. The base 2415 is defined by a material and thickness. The underlying dielectric layers 2420 are defined by a material type and thickness td2 of each layer. The piezoelectric wafer 2410 is defined by a material type, thickness tp, and orientation of the crystalline axes of the piezoelectric material. The conductor pattern 2405 is defined by its thickness and material. The dielectric layer 2425 is defined by the thickness td1 and material. When multiple acoustic wave resonators 2400 are incorporated into a filter, the material stack may include additional layers as previously described.

FIG. 24B is a schematic cross-section view of a fourth exemplary acoustic wave resonator 2450. The fourth acoustic wave resonator 2450 will be referred to herein as a “solidly-mounted membrane resonator.” A solidly mounted membrane resonator is characterized by a conductor pattern 2455 including an IDT formed on a surface of a thin membrane 2460 of single-crystal piezoelectric material supported by a non-piezoelectric base 2465, with an acoustic Bragg reflector 2470 sandwiched between the membrane 2460 and the base 2465. The acoustic Bragg reflector 2470 includes multiple layers alternating between a first material having high acoustic impedance and a second material having low acoustic impedance. The acoustic Bragg reflector 2470 is configured to reflect and confine acoustic waves generated with the membrane 2460. A dielectric layer 2475 may be deposited over and between the fingers of the conductor pattern 2455.

The material stack for a solidly mounted membrane resonator 2450 includes the base 2465, the acoustic Bragg reflector 2470, the piezoelectric membrane 2460, the conductor pattern 2455 and the dielectric layer 2475. The base 2465 is defined by a material and thickness. The acoustic Bragg reflector 2470 is defined by the first and second material types, the number of layers, and the thickness of each layer. The piezoelectric membrane 2460 is defined by a material type, thickness tp, and orientation of the crystalline axes of the piezoelectric material. The conductor pattern 355 is defined by its thickness and material. The dielectric layer 2475 is defined by the thickness td1 and material. When multiple solidly mounted membrane resonators are incorporated into a filter device, the material stack may include additional layers as previously described.

FIG. 25A is a schematic cross-section view of a fifth exemplary acoustic wave resonator 2500. The fifth acoustic wave resonator 2500 is a film bulk acoustic resonator (FBAR). The fifth acoustic wave resonator 2500 includes a thin wafer or film 2505 of single-crystal piezoelectric material sandwiched between upper and lower conductors 2520 and 2515, respectively. This sandwich is support by a non-piezoelectric base 2510. A cavity 2525 is formed in the base 2510 such that a portion of the sandwich 2515/2505/2520 forms a diaphragm spanning the cavity 2525.

The material stack for the FBAR 2500 includes the base 2510, the lower conductor layer 2515, the piezoelectric wafer or film 2505, and the upper conductor layer 2520. The base 2510 is defined by a material and thickness. The lower conductor layer 2515 is defined by a material type and thickness. The piezoelectric wafer or film 2505 is defined by a material type, thickness, and orientation of the crystalline axes of the piezoelectric material. The upper conductor layer 2520 is defined by its thickness and material. When multiple FBARs 2500 are incorporated into a filter, the material stack may include additional layers as previously described.

FIG. 25B is a schematic cross-section view of a sixth exemplary acoustic wave resonator 2550. The sixth acoustic wave resonator will be referred to herein as a “solidly-mounted film bulk acoustic resonator” (SM-FBAR). The sixth acoustic wave resonator 2550 includes a thin wafer or film 2555 of single-crystal piezoelectric material sandwiched between upper and lower conductors 2570 and 2565, respectively. This sandwich is support by a non-piezoelectric base 2560. An acoustic Bragg reflector 2575 is sandwiched between the sandwich 2570/2555/2565 and the base 2560. The acoustic Bragg reflector 2575 includes multiple layers alternating between a first material having high acoustic impedance and a second material having low acoustic impedance. The acoustic Bragg reflector 2575 is configured to reflect and confine acoustic waves generated with the sandwich 2570/2555/2565.

The material stack for the SM-FBAR 450 includes the base 2560, the acoustic Bragg reflector 2575, the lower conductor layer 2565, the piezoelectric wafer or film 2555, and the upper conductor layer 2570. The base 2560 is defined by a material and thickness. The acoustic Bragg reflector 2575 is defined by the first and second material types, the number of layers, and the thickness of each layer. The lower conductor layer 2565 is defined by a material type and thickness. The piezoelectric wafer or film 2555 is defined by a material type, thickness, and orientation of the crystalline axes of the piezoelectric material. The upper conductor layer 2570 is defined by its thickness and material. When multiple SM-FBARs 2550 are incorporated into a filter, the material stack may include additional layers as previously described.

The acoustic resonators shown in FIG. 232A through FIG. 25B are not an all-inclusive list of acoustic resonator types. Other types of acoustic resonators, having other material stacks, may be used in filters. Further, the cross-sectional views of FIG. 23A through FIG. 25B do not necessarily show all layers in the respective material stacks. Additional layers may be present, for example, to promote adhesion between other layers, prevent chemical interaction between other layers, or to passivate and protect other layers.

FIG. 26 is an exemplary schematic plan view of a conventional implementation of a band-pass filter 2600, which has the same schematic diagram as the band-pass filter circuit 2200 of FIG. 22A. In the filter 2600, all six acoustic wave resonators X1-X6 are formed on a common chip 2610. All of the acoustic wave resonators X1 to X6 may be non-bonded SAW resonators, bonded wafer resonators, floating diaphragm resonators, solidly mounted membrane resonators, FBARs, SM-FBARs, or some other type of acoustic wave resonators. All of the acoustic wave resonators X1 to X6 are typically the same type of resonator. For ease of preparation of the figure, all of the resonators X1-X6 are the same size in FIG. 26. This is almost certainly not the case in an actual filter.

The acoustic wave resonators X1-X6 are interconnected by conductors, such as conductor 2630, formed on the substrate 2610. The filter 2600 is electrically connected to a system external to the filter by means of pads, such as pad 2620. Each pad may, for example, be or interface with a solder or gold bump to connect with a circuit board (not shown). In addition to establishing electrical connections, the pads and bumps are typically the primary means to remove heat from the filter 2600.

When multiple acoustic wave resonators are formed on the same chip, the fabrication processes and material stack are inherently the same for all of the multiple resonators. In particular, the piezoelectric element (i.e. the plate, wafer, or film of piezoelectric material) within the material stack is the same for all resonators. However, the requirements on shunt resonators and series resonators are typically different, as summarized in the following table:

| Shunt Resonators | Series Resonators |
|---|---|
| High Q at resonance frequency | High Q at anti-resonance frequency |
| Low temperature coefficient of | Low temperature coefficient of |
| frequency at resonance frequency | frequency at anti-resonance |
| | frequency |
| Lower resonance frequency | Higher resonance frequency |
| Higher capacitance | Lower capacitance |
| Lower power dissipation | Higher power dissipation |

It may not be possible to select a material stack that is optimum, or even adequate, for all of the resonators in a filter.

FIG. 27 is an exemplary schematic plan view of a split ladder filter 2700, which has the same schematic diagram as the ladder filter circuit 2200 of FIG. 22A. In contrast to the conventional filter 2600 shown in FIG. 26, the series resonators X1, X3, X5 of the split ladder filter 2700 are fabricated on a first chip 2710 and the shunt resonators X2, X4, X6 of the split ladder filter 2700 are on fabricated on a second chip 2740. Within each chip 2710, 2740, the acoustic wave resonators are interconnected by conductors, such as conductor 2730, formed on the respective chip. The chips 2710, 2740 are electrically connected to each other and to a system external to the filter by means of pads, such as pad 2720. Each pad may, for example, be, or interface with, a solder or gold bump to connect with a circuit card (not shown).

Electrical connections 2750 between the series resonators on the first chip 2710 and the shunt resonators on the second chip 2740 are shown as bold dashed lines. The connections 2750 are made, for example, by conductors on a circuit card to which the first and second chips are mounted. In this context, the term “circuit card” means an essentially planar structure containing conductors to connect the first and second chips to each other and to a system external to the band-pass filter 2700. The circuit card may be, for example, a single-layer or multi-layer printed wiring board, a low temperature co-fired ceramic (LTCC) card, or some other type of circuit card. Traces on the circuit card can have very low resistance such that losses in the traces are negligible. The inductance of the electrical connections 2750 between the series and shunt resonators can be compensated in the design of the acoustic wave resonators. In some cases, the inductance of the electrical connections 2750 can be exploited to improve the performance of the filter, for example by lowering the resonance frequency of one or more shunt resonators to increase the filter bandwidth.

In the exemplary split ladder filter 2700, all of the series resonators are on the first chip and all of the shunt resonators are on the second chip. However, this is not necessarily the case. In some filters, the first chip may contain less than all of the series resonators and/or the second chip may contain less than all of the shunt resonators.

FIG. 28 is a schematic cross-sectional view of a split ladder filter 2800 which may be the split ladder filter 2800. The split ladder filter 2800 includes a first chip 2810 and a second chip 2840 attached to, and interconnected by, a circuit card 2870. In this example, the first and second chips 2810, 2840 are “flip-chip” mounted to the circuit card 2870. Electrical connections between the first and second chips 2810, 2840 and the circuit card 2870 are made by solder or gold bumps, such as bump 2820. Electrical connections between the first chip 2810 and the second chip 2840 are made by conductors, such as conductor 2850, on or within the circuit card 2870. The first and second chips 2810, 2840 may be mounted on and/or connected to the circuit card 2870 in some other manner.

The benefit of a split ladder filter, such as the split ladder filters 2700 and 2800, is different material stacks can be used for the series resonators and the shunt resonators. A first material stack may be used for the first chip containing some or all series resonators and a second material stack may be used for a second chip containing some or all shunt resonators. The first and second material stacks may be different. This allows separate optimization of the first and second material stacks for series resonators and shunt resonators.

Two material stacks are considered different if they differ in at least one aspect of at least one element within the stacks. The difference between material stacks may be, for example, the sequence of the elements or a different material type, thickness, or other parameter for at least one element in the stack. Commonly, the first material stack includes a first piezoelectric element and the second material stack includes a second piezoelectric element which differs from the first piezoelectric element in at least one of a material, a thickness, and an orientation of the crystalline axes of the material.

When the split ladder filters 2700/2800 incorporate non-bonded SAW resonators as shown in FIG. 23A, the first material stack and the second material stack may differ in one or more of the following characteristics: the material type, thickness, and orientation of the crystalline axes of the piezoelectric plate 2305; the material and/or thickness h of the conductor pattern 2310; and the thickness td1 and material of the dielectric layer 2315.

When the split ladder filters 2700/2800 incorporate bonded wafer resonators as shown in FIG. 23B, the first material stack and the second material stack may differ in one or more of the following characteristics: the material and thickness of the base 2330; the number of underlying dielectric layers 2340, if any, and the material and thickness td2 of each layer; the material type, thickness tp, and orientation of the crystalline axes of the piezoelectric wafer 2325; the thickness h and material of the conductor pattern 2335; and the thickness td1 and material of the dielectric layer 2345.

When the split ladder filters 2700/2800 incorporate floating diaphragm resonators as shown in FIG. 24A, the first material stack and the second material stack may differ in one or more of the following characteristics: the material and thickness of the base 2415; the number of underlying dielectric layers 2420, if any, and the material and thickness td2 of each layer; the material type, thickness tp, and orientation of the crystalline axes of the piezoelectric wafer 2410; the thickness h and material of the conductor pattern 2405; and the thickness td1 and material of the dielectric layer 2425.

When the split ladder filters 2700/2800 incorporate solidly mounted membrane resonators as shown in FIG. 24B, the first material stack and the second material stack may differ in one or more of the following characteristics: the material and thickness of the base 2465; the number layers and the material and thickness of each layer in the acoustic Bragg reflector 2470; the material type, thickness tp, and orientation of the crystalline axes of the piezoelectric wafer 2460; the thickness h and material of the conductor pattern 2465; and the thickness td1 and material of the dielectric layer 2475.

When the split ladder filters 2700/2800 incorporate FBARs as shown in FIG. 25A, the first material stack and the second material stack may differ in one or more of the following characteristics: the material and thickness of the base 2510; the material and thickness of the lower conductor 2515; the material type, thickness tp, and orientation of the crystalline axes of the piezoelectric wafer 2505; and the thickness and material of the upper conductor 2520.

When the split ladder filters 2700/2800 incorporate SM-FBARs as shown in FIG. 25B, the first material stack and the second material stack may differ in one or more of the following characteristics: the material and thickness of the base 2560; the number layers and the material and thickness of each layer in the acoustic Bragg reflector 2575; the material and thickness of the lower conductor 2565; the material type, thickness tp, and orientation of the crystalline axes of the piezoelectric wafer 2555; and the thickness and material of the upper conductor 2570.

The differences between the first material stack and the second material stack of a split ladder filter are not necessarily identified in the preceding six paragraphs. The first material stack and the second material stack may differ in one or more parameters in addition to, or instead of, the parameters identified herein. The types of resonators are not limited to the types illustrated in FIG. 23A through FIG. 25B. Further, the series resonators and the shunt resonators need not be the same type of resonator.

### Example 1

A desired characteristic of filters for use in portable devices is stability of the filter passband over a wide range of temperatures. A technology to achieve, at least in part, that objective is to fabricate the filter with bonded-wafer resonators using a thin wafer of piezoelectric material bonded to a base, such as a silicon substrate, that has a low thermal expansion coefficient and high thermal conductivity. A bonded-wafer SAW filter will have lower temperature rise for a given power input and reduced sensitivity of the passband frequency to temperature compared to a filter using non-bonded SAW resonators.

A disadvantage of bonded-wafer SAW resonators is the presence of spurious acoustic modes that can propagate within the piezoelectric material or into the silicon wafer or other base. A key element of the design of a bandpass filter using bonded-wafer resonators is to ensure that the spurious modes occur at frequencies away from the filter passband. The cross-sectional structure and material stack for a bonded-wafer SAW resonator is similar to the resonator 250 of FIG. 2B.

FIG. 8 is a graph 2900 of the magnitude of S12 for two bonded-wafer SAW filters fabricated using lithium tantalate (LT) wafers bonded to silicon bases. S12 is the transmission between the first and second ports of the filter. The dot-dash line 2910 is a plot of S12 for a filter fabricated on a 42-degree Y-cut LT wafer. The dashed line 2920 is a plot of S12 for a filter fabricated on a 46-degree Y-cut LT wafer. The bold line 2930 defines a requirement (less than 2 dB insertion loss over the transmission band from 1850 MHz to 1910 MHz) for an LTE (Long Term Evolution) Band 2 transmit filter.

When the filter is fabricated on 42-degree LT (dot-dash line 2910), spurious modes occur at frequencies around the anti-resonance frequencies of the series resonators in the filter. These spurious modes reduce S12 (and correspondingly increase insertion loss) near the upper edge of the filter passband, between 1902 MHz and 1915 MHz. When the filter is fabricated on 46-degree LT (dashed line 2920), spurious modes occur at frequencies around the resonance frequencies of the shunt resonators. These spurious modes reduce S12 (and correspondingly increase insertion loss) between 1845 MHz and 1855 MHz. Neither of these filters meets the requirement of less than 2 dB insertion loss over the LTE Band 2 transmission band.

FIG. 30 is a graph 3000 of the magnitude of S12 (curve 910) for a split-ladder LTE Band 2 transmit filter fabricated on two chips, each of which has a lithium tantalate (LT) wafer bonded to a silicon base. The first chip contains series resonators fabricated on 46-degree LT. The second chip contains shunt resonators fabricated on 42-degree LT. The material stacks for the first chip and the second chip differ by at least the orientation of the crystalline axis of the respective LT wafers and may differ in other ways.

Using 46-degree LT for the series resonators avoids the losses at the upper edge of the passband due to spurious modes that were evident in the curve 3010. Using 42-degree LT for the shunt resonators avoids the losses at the lower edge of the passband due to spurious modes that were evident in the curve 2920. As shown in FIG. 30, the split ladder filter meets the LTE Band 2 transmit filter insertion loss requirement (bold line 3030), in contrast to the performance of either conventional (i.e. single-chip) ladder filter shown in FIG. 29.

### Example 2

For most acoustic wave resonators, increasing temperature causes both the resonance and anti-resonance frequencies to shift to a lower frequency. A reduction in the resonance frequency of shunt resonators increases the margin between the lower edge of the filter passband and the lower edge of the actual frequency band. Thus the impact of temperature on shunt resonators may be small. Conversely, a reduction in the anti-resonance frequency of series resonators reduces the margin between the upper edge of the filter passband and the upper edge of the actual frequency band. This effect may be accompanied by increased power dissipation in the series resonators. Thus the benefits of bonded-wafer resonators (low temperature coefficient of frequency and high thermal conductivity to limit temperature rise) are more significant for series resonators than for shunt resonators. A split-ladder filter including a first chip with bonded-wafer series resonators and a second chip with non-bonded SAW shunt resonators provides lower cost than the previous Example 1 while maintaining the benefits of using bonded-wafer series resonators.

### Example 3

Many of the frequency bands used by portable communications devices are “frequency division duplex” (FDD) bands, which is to say separate frequency ranges or bands are used for signals transmitted from and received by the device. A duplexer is a filter subsystem to separate the transmit frequency band from the receive frequency band. Typically, a duplexer includes a transmit filter that accepts a transmit signal from a transmitter and delivers a filtered transmit signal to an antenna, and a receive filter that accepts a receive signal from the antenna and delivers a filtered receive signal to a receiver.

A duplexer may be implemented as two filters on a common chip using the same material stack for both the transmit filter and the receive filter. Alternatively, a duplexer 3100 may be implemented with the transmit filter and receive filter on separate chips, as shown in FIG. 31A. A first chip 3110 contains the transmit filter and a second chip 3120 contains the receive filter. Pads on the chips 3110, 3120 connect to a circuit card as previously described. The pad labels “Tx” is the input from a transmitter. The pad labeled “Rx” is the output to a receiver. Pads labeled “A” connect to an antenna. Pads labeled “G” connect to ground. FIG. 31A illustrates the concept of a two-chip duplexer rather than a specific duplexer design. For ease of preparation, the transmit filter on the first chip 3110 is the same as the filter shown in FIG. 26 and the receive filter on the second chip 3120 is a mirror image of the filter of FIG. 26.

Implementing a duplexer with the transmit filter and receive filter on different chips allows the material stack for the two filters to be different. Two-chip implementations may be appropriate for frequency division duplex bands where the transmit and receive frequency bands are widely separated. For example, LTE band 4 has 400 MHz separation between the transmit band (1710 MHz to 1755 MHz) and the receive band (2110 MHz to 2155 MHz). Implementing a LTE band 4 duplexer with the transmit filter and receive filter on different chips allows the material stack for the two filters to be optimized for the respective frequency ranges.

FIG. 31B is an exemplary schematic plan view of a split ladder duplexer 3150 including a transmit filter and a receive filter, each of which has the same schematic diagram as the band-pass filter circuit 2200 of FIG. 22A. The transmit filter includes series resonators XT1, XT3, and XT5 and shunt resonators XT2, XT4, and XT6. The receive filter includes series resonators XR1, XR3, and XR5 and shunt resonators XR2, XR4, and XR6. In contrast to the two-chip duplexer 3100 shown in FIG. 31A, the series resonators XT1, XT3, XT5, XR1, XR3, XR5 of both the transmit filter and the receive filter are fabricated on a first chip 3160. The shunt resonators XT2, XT4, XT6, XR2, XR4, XR6 of both the transmit filter and the receive filter are fabricated on a second chip 3170. The chips 3160, 3170 are electrically connected to each other and to a system external to the filter by means of pads and as a circuit card as previously described. Each pad may, for example, be, or interface with, a solder or gold bump to connect with on the circuit card (not shown). Electrical connections 2750 between the series resonators on the first chip 3160 and the shunt resonators on the second chip 3170 are shown as bold dashed lines. The connections 2750 are made, for example, by conductors on the circuit card to which the first and second chips 3160, 3170 are mounted.

The transmit filter may be, for example, the LTE band 2 transmit split ladder filter described in conjunction with FIG. 29 and FIG. 30. The receive filter may be similar to the split ladder filter with a passband from 1930 MHz to 1990 MHz.

### Example 4

FIG. 32 is an exemplary schematic plan view of another split ladder duplexer 3200 including a transmit filter and a receive filter, each of which has the same schematic diagram as the band-pass filter circuit 2200 of FIG. 1A. The transmit filter includes series resonators XT1, XT3, and XT5 and shunt resonators XT2, XT4, and XT6. The receive filter includes series resonators XR1, XR3, and XR5 and shunt resonators XR2, XR4, and XR6. The series resonators XT1, XT3, XT5 of the transmit filter are fabricated on a first chip 3260. The shunt resonators XT2, XT4, XT6 of the transmit filter and all of the resonators XR1, XR2, XR3, XR4, XR5, XR6 of the receive filter are fabricated on a second chip 3270. The chips 3260, 3270 are electrically connected to each other and to a system external to the filter by means of pads and as a circuit card as previously described.

The series resonators XT1, XT3, XT5 of the transmit filter on the first chip 3260 have high power dissipation compared to the resonators on the second chip 3220. Thus, the first chip may have a material stack that provides efficient heat removal from the resonators. The series resonators XT1, XT3, XT5 of the transmit filter may be, for example, bonded wafer resonators or solidly mounted membrane resonators. The second chip, where heat removal is not as significant, may be fabricated using a different type of resonator. The resonators on the second chip may be, for example, non-bonded SAW resonators.

### Description of Methods

FIG. 33 is a flow chart of a method 3300 for fabricating a split-ladder filter device, which may be the split ladder filter devices 2700, 2800, or 3150. The method 3300 starts at 310 and concludes at 3390 with a completed filter device.

At 3320, a first chip is fabricated using a first material stack. The first chip contains one, some, or all of the series resonators of the filter device. The first chip may be a portion of a first large multi-chip wafer such that multiple copies of the first chip are produced during each repetition of the step 3320. In this case, individual chips may be excised from the wafer and tested as part of the action at 3320.

At 3330, a second chip is fabricated using a second material stack that is different from the first material stack. The second chip contains one, some, or all of the shunt resonators of the filter device. The second chip may be a portion of a second large multi-chip wafer such that multiple copies of the second chip are produced during each repetition of the step 3330. In this case, individual chips may be excised from the wafer and tested as part of the action at 3330.

At 3340, a circuit card is fabricated. The circuit card may be, for example, a printed wiring board or an LTCC card or some other form of circuit card. The circuit card may include one or more conductors for making at least one electrical connection between a series resonator on the first chip and a shunt resonator on the second chip. The circuit may be a portion of large substrate such that multiple copies of the circuit card are produced during each repetition of the step 3340. In this case, individual circuit cards may be excised from the substrate and tested as part of the action at 3340. Alternatively, individual circuit cards may be excised from the substrate after chips have been attached to the circuit cards at 3350, or after the devices are packaged at 3360.

At 3350, individual first and second chips are assembled to a circuit card (which may or may not be a portion of a larger substrate) using known processes. For example, the first and second chips may be “flip-chip” mounted to the circuit card using solder or gold bumps or balls to make electrical, mechanical, and thermal connections between the chips and the circuit card. The first and second chips may be assembled to the circuit card in some other manner.

The filter device is completed at 3360. Completing the filter device at 3360 includes packaging and testing. Completing the filter device at 3360 may include excising individual circuit card/chip assemblies from a larger substrate before or after packaging.

### CLOSING COMMENTS

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A filter device comprising:
a first chip comprising:
a substrate including a base and an intermediate layer;
a piezoelectric layer attached to the substrate; and
a conductor pattern on a surface of the piezoelectric layer, the conductor pattern including interleaved fingers of a plurality of interdigital transducers (IDTs) of a plurality of resonators;
a first dielectric layer of the first chip having a first thickness disposed on and between the interleaved fingers of a first resonator of the plurality of resonators of the first chip;
a second dielectric layer of the first chip having a second thickness greater than the first thickness of the first chip disposed on and between the interleaved fingers of a second resonator of the plurality of resonators of the first chip,
wherein each IDT comprises a first busbar, a second busbar, and the interleaved fingers extending alternately from the first and second busbars, wherein overlapping portions of the interleaved fingers are disposed on the piezoelectric layer; and
a second chip comprising:
a substrate including a base and an intermediate layer;
a piezoelectric layer attached to the substrate; and
a conductor pattern on a surface of the piezoelectric layer, the conductor pattern including interleaved fingers of a plurality of interdigital transducers (IDTs) of a plurality of resonators;
a first dielectric layer of the second chip having a first thickness disposed on and between the interleaved fingers of a first resonator of the plurality of resonators of the second chip;
a second dielectric layer of the second chip having a second thickness greater than the first thickness of the second chip disposed on and between the interleaved fingers of a second resonator of the plurality of resonators of the second chip,
wherein each IDT comprises a first busbar, a second busbar, and the interleaved fingers extending alternately from the first and second busbars, wherein overlapping portions of the interleaved fingers are disposed on the piezoelectric layer.

2. The filter device of claim 1, wherein:
the intermediate layer includes one or more cavities,
the piezoelectric layer forms one or more diaphragms that are over the cavities; and
the interleaved fingers of each of the plurality of IDTs are disposed on a respective diaphragm of the one or more diaphragms.

3. The filter device of claim 1, wherein:
the substrate includes an acoustic Bragg reflector that is sandwiched between the piezoelectric layer and the base,
a portion of the piezoelectric layer is provided over the acoustic Bragg reflector; and
the interleaved fingers of each of the plurality of IDTs are disposed on the portion of the piezoelectric layer.

4. The filter device of claim 1, wherein the piezoelectric layer and all of the IDTs are configured such that a respective radio frequency signal applied to each IDT excites a respective primary shear acoustic mode within the piezoelectric layer, wherein shear deformation is introduced by a lateral electric field in a substantially lateral direction of atomic motion, while propagation of a bulk shear wave of the shear acoustic mode is normal to the substantially lateral direction of atomic motion and also substantially normal to the surface of the piezoelectric layer.

5. The filter device of claim 1, wherein the first and second resonators of the second chip includes two or more shunt resonators and first and second resonators of the first chip includes two or more series resonators connected to form a ladder filter circuit, and the second chip includes all of the shunt resonators.

6. The filter device of claim 5, wherein the first chip includes all of the series resonators.

7. The filter device of claim 1, further comprising a back-side dielectric layer on the surface of the piezoelectric layer facing the substrate, wherein the back-side dielectric layer is a different thickness than the either the first dielectric layer or the second dielectric layer.

8. The filter device of claim 1, wherein the first and second resonators of the first chip are sub-resonators having substantially a same aperture and substantially a same length.

9. The filter device of claim 1, wherein the first resonator of the plurality of resonators of the first chip is one of a first subset of resonators of the plurality of resonators of the first chip, wherein the first subset of resonators all comprise the first dielectric layer thickness, and wherein the second resonator of the plurality of resonators of the first chip is one resonator of a second substrate of resonators of the plurality of resonators of the second chip, and wherein the second subset of resonators all have the first dielectric layer thickness.

10. A filter device, comprising:
a first chip comprising:
a substrate,
a piezoelectric layer attached either directly or via one or more intermediate layers the substrate, and
one or more electrodes of a respective plurality of resonators of the first chip including a shunt resonator of the first chip;
a first dielectric layer having a first thickness at least partially on the one or more electrodes of the shunt resonator;
a second chip comprising:
a substrate,
a piezoelectric layer attached either directly or via one or more intermediate layers to the substrate, and
one or more electrodes of a respective plurality of resonators of the second chip including a series resonator of the second chip; and
a second dielectric layer having a second thickness different than the first thickness at least partially on the one or more electrodes of the series resonator of the second chip.

11. The filter device of claim 10, wherein:
for one or more of the first and second chip, the intermediate layer includes one or more cavities,
the piezoelectric layer forms one or more diaphragms that are over the cavities; and
the one or more electrodes disposed on a respective diaphragm of the one or more diaphragms.

12. The filter device of claim 10, wherein:
for one or more of the first and second chip the substrate includes an acoustic Bragg reflector that is sandwiched between the piezoelectric layer and the substrate,
a portion of the piezoelectric layer is provided over the acoustic Bragg reflector; and
the one or more electrodes disposed on the portion of the piezoelectric layer.

13. The filter device of claim 10, wherein a difference between a resonance frequency of the series resonator and a resonance frequency of the shunt resonator is determined, in part, by a difference between the first thickness and the second thickness.

14. The filter device of claim 10, wherein the first thickness is less than or equal to 500 nanometers (nm), and the second thickness is greater than zero.

15. The filter device of claim 10, wherein respective directions of acoustic energy flow of each excited primary shear acoustic modes are substantially normal to one or more surfaces of the piezoelectric layer, and substantially normal to a lateral direction of an electric field of the primary shear acoustic mode.

16. The filter device of claim 10, wherein a thickness of the piezoelectric layer is measured between a front surface and a back surface and is greater than or equal to 100 nanometers (nm) and less than or equal to 1000 nm.

17. The filter device of claim 10, wherein the one or more electrodes is an interdigital transducer having interleaved fingers with each having a respective pitch greater than or equal to 2 times the thickness of the piezoelectric layer and less than or equal to 25 times the thickness of the piezoelectric layer.

18. The filter device of claim 10, wherein the first and second dielectric layers comprise at least one of silicon oxide and silicon nitride.

19. The filter device of claim 10, wherein the one or more electrodes of the first chip and the second chip comprises one of aluminum, an aluminum alloy, copper, a copper alloy, beryllium, and gold.

20. The filter device of claim 10, wherein:
the shunt resonator of the first chip is a first shunt resonator from among a plurality of shunt resonators on the first chip, and
the filter device further comprises a second shunt resonator on the first chip, the second shunt resonator having a third dielectric layer of a third thickness that is different than the first thickness.
